(19) United States
(12) Patent Application Publication
(10) Pub. No.: US 2025/0216782 A1
(43) Pub. Date: Jul. 3, 2025

(54) MASKING PROCESS USING SWITCHABLE POLYMER

(71) Applicants: Tokyo Electron Limited, Tokyo (JP); Geminatio, Inc., Schenectady, NY (US)

(72) Inventors: Phillip D. Hustad, Longmont, CO (US); Jordan B. Greenough, Schenectady, NY (US); Max J. Klemes, Schenectady, NY (US)

(21) Appl. No.: 18/988,498

(22) Filed: Dec. 19, 2024

Related U.S. Application Data
(60) Provisional application No. 63/616,077, filed on Dec. 29, 2023.

(51) Int. Cl. G03F 7/038; G03F 7/00; G03F 7/11; G03F 7/32; H01L 21/027

(52) U.S. Cl. CPC G03F 7/0382; G03F 7/0005; G03F 7/0035; G03F 7/11; G03F 7/322; H01L 21/0274

(57) ABSTRACT

A method for forming a patterned mask can include providing first and second structures on a substrate, where the first structure includes a solubility shifting agent therein, and where the first structure is insoluble in a first developer containing an organic solvent, where the second structure includes a first polymer and a first reactant, and where the second structure is insoluble in the first developer containing the organic solvent, and diffusing at least a catalyst portion of the solubility shifting agent from the first structure into a first region of the second structure and chemically transforming the first region of the second structure to a converted region of a converted material to a first depth into the second structure using the catalyst portion of the solubility shifting agent as a chemical reaction catalyst, such that the converted material is soluble in the first developer containing the organic solvent.

### CROSS-REFERENCE TO RELATED APPLICATIONS

This application claims the priority and benefit of U.S. Provisional Application No. 63/616,077, filed on Dec. 29, 2023, which application is hereby incorporated herein by reference in its entirety.

### TECHNICAL FIELD

The present disclosure relates generally to methods for forming an anti-spacer patterned mask, and more particularly, photolithography materials and processes in methods for forming an anti-spacer patterned mask during manufacturing of semiconductor devices.

### BACKGROUND

In photolithography for semiconductor manufacturing, a relief pattern can be topographical variation created on a surface of and/or through a photoresist material layer. A relief pattern can be formed when portions of a photoresist material layer are selectively exposed to light and then chemically developed, resulting in regions with different heights or levels, such as trenches and holes formed in and patterned in a layer or film of photoresist material. The photoresist material is a light-sensitive material that undergoes chemical changes when exposed to ultraviolet (UV) light or extreme ultraviolet (EUV) light (e.g., light with a wavelength of 13.5 nm). The photoresist material is typically exposed to a patterned light through a mask or directly using a laser. The pattern transferred to the photoresist material by exposure to light defines exposed areas and regions of the photoresist material.

In positive photoresist, the exposed regions become soluble and can be removed in a development process by chemicals of a developer solvent. In negative photoresist, the exposed regions become insoluble, and the unexposed areas can be removed in a development process by chemicals of a developer solvent. After exposure and pattern transfer, the wafer can be subjected to a chemical developer that dissolves the soluble parts of the photoresist to create a relief pattern on the surface of and/or through the photoresist material layer, such that the exposed (or unexposed) areas are removed, leaving behind patterned features. Then, this relief pattern can be used as a mask for further processing steps, such as etching or ion implantation, to transfer the pattern (design) into underlying layers and/or a substrate of the wafer.

In material processing methodologies (such as photolithography), creating patterned layers typically involves the application of a thin layer of radiation-sensitive material, such as photoresist, to an upper surface of a substrate. This radiation-sensitive material is transformed into a patterned mask that can be used to etch or transfer a pattern into an underlying layer on a substrate. Patterning of the radiation-sensitive material generally involves exposure by a radiation source through a reticle (and associated optics) onto the radiation-sensitive material using, for example, a photolithographic exposure system.

This exposure creates a latent pattern within the radiation-sensitive material which can then be developed. Developing refers to dissolving and removing a portion of the radiation-sensitive material to yield a relief pattern (topographic pattern). The portion of material removed can be either irradiated regions or non-irradiated regions of the radiation-sensitive material depending on a photoresist tone and/or type of developing solvent used. The relief pattern can then function as a mask layer defining a pattern.

Preparation and development of various films used for patterning can include thermal treatment (e.g. baking). For example, a newly applied film can receive a post-application bake (PAB) to evaporate solvents and/or to increase structural rigidity or etch resistance. Also, a post-exposure bake (PEB) can be executed to set a given pattern to prevent further dissolving. Fabrication tools for coating and developing substrates typically include one or more baking modules. Some photolithography processes include coating a substrate with a thin film of bottom anti-reflective coating (BARC), followed by coating with a resist, and then exposing the substrate to a pattern of light as a process step for creating microchips. A relief pattern created can then be used as a mask or template for additional processing such as transferring the pattern into an underlying layer.

The minimum resolution attainable with a single lithographic exposure is limited, amongst other things, by the wavelength of light used (the so-called diffraction limit). Techniques such as immersion lithography can be utilized to lower the diffraction limit. Multiple patterning processes such as Self-Aligned Double Patterning (SADP) are increasingly being used for scaling semiconductor features below photolithographic limits. Multiple patterning processes can double pitch (for each additional patterning) and thus help to achieve feature sizes that are otherwise unattainable.

However, multiple patterning processes are frequently costly and complex. Additionally, multiple patterning process flows can be incompatible with high volume manufacturing. Further, many multiple patterning techniques require additional process steps such as etching, deposition, development, and treatments which also increase complexity and reduce throughput. Therefore, multiple pattern processes that reduce cost, reduce complexity, and/or increase compatibility are desirable.

### SUMMARY

In accordance with an embodiment of the present disclosure, a method for forming a patterned mask can include: providing a first intermediate structure on a substrate, where the first intermediate structure includes a first material, where the first material includes a solubility shifting agent therein, and where the first material is insoluble in a first developer containing an organic solvent; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent; and diffusing at least a catalyst portion of the solubility shifting agent from the first material into the first region of the second intermediate structure and chemically transforming the first region of the second intermediate structure to a converted region of a third material to a first depth into the second intermediate structure using the catalyst portion of the solubility shifting agent as a chemical reaction catalyst, such that the third material is soluble in the first developer containing the organic solvent.

In accordance with an embodiment of the present disclosure, a method for forming an anti-spacer patterned mask can include: providing a first patterned photoresist layer on a substrate, where the first patterned photoresist layer includes a solubility shifting agent therein, and where the first patterned photoresist layer is insoluble in a first developer containing an organic solvent; depositing a first overcoat layer over the first patterned photoresist layer and the substrate, where the first overcoat layer includes a first polymer and a first reactant, where the first overcoat layer is insoluble in the first developer containing the organic solvent; diffusing at least a catalyst portion of the solubility shifting agent from the first patterned photoresist layer into first regions of the first overcoat layer, where the first regions are adjacent the first patterned photoresist layer, and chemically transforming the first regions of the first overcoat layer to anti-spacer regions of a converted material to a first depth into the first overcoat layer using the catalyst portion of the solubility shifting agent as a chemical reaction catalyst, such that the converted material is soluble in the first developer containing the organic solvent; and removing the anti-spacer regions using the organic solvent of the first developer to form an anti-spacer pattern including remaining portions of the first patterned photoresist layer and the first overcoat layer having openings to the substrate corresponding to the anti-spacer regions and where at least part of the openings has a critical dimension corresponding to the first depth.

In accordance with an embodiment of the present disclosure, a method for forming an anti-spacer patterned mask can include: providing a first patterned photoresist layer on a substrate, where the first patterned photoresist layer includes a first polymer and a first reactant, where the first patterned photoresist layer is insoluble in a first developer containing an organic solvent; depositing a first overcoat layer over the first patterned photoresist layer and the substrate, where the first overcoat layer includes a solubility shifting agent therein, and where the first overcoat layer is insoluble in the first developer containing the organic solvent; diffusing at least a catalyst portion of the solubility shifting agent from the first overcoat layer into outer regions of the first patterned photoresist layer and chemically transforming the outer regions of the first patterned photoresist layer to anti-spacer regions of a converted material to a first depth into the first patterned photoresist layer using the catalyst portion of the solubility shifting agent as a chemical reaction catalyst, such that the converted material is soluble in the first developer containing the organic solvent; and removing the anti-spacer regions using the organic solvent of the first developer to form an anti-spacer pattern including remaining portions of the first overcoat layer and the first patterned photoresist layer having openings to the substrate corresponding to the anti-spacer regions and where at least part of the openings has a critical dimension corresponding to the first depth.

In accordance with an embodiment of the present disclosure, a method for forming an anti-spacer patterned mask can include: providing a first intermediate structure on a substrate, where the first intermediate structure includes a first material, where the first material includes a solubility shifting agent therein, and where the first material is insoluble in a first developer containing an organic solvent; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent; diffusing at least a catalyst portion of the solubility shifting agent from the first material into the first region of the second intermediate structure and chemically transforming the first region of the second intermediate structure to an anti-spacer region of a third material to a first depth into the second intermediate structure using the catalyst portion of the solubility shifting agent as a chemical reaction catalyst, such that the third material is soluble in the first developer containing the organic solvent; and removing the anti-spacer region using the organic solvent of the first developer to form an anti-spacer pattern including remaining portions of the first intermediate structure and the second intermediate structure having an opening to the substrate corresponding to the anti-spacer region and where at least part of the opening has a critical dimension corresponding to the first depth.

In accordance with an embodiment of the present disclosure, a method for forming a patterned mask can include: providing a first intermediate structure on a substrate, where the first intermediate structure includes a first material, where the first material includes a solubility shifting agent therein, and where the first material is soluble in a first developer containing a quaternary ammonium hydroxide in an aqueous solution; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is soluble in the first developer containing the quaternary ammonium hydroxide; diffusing at least a catalyst portion of the solubility shifting agent from the first material into the first region of the second intermediate structure and chemically transforming the first region of the second intermediate structure to a mandrel region of a third material to a first depth into the second intermediate structure using the catalyst portion of the solubility shifting agent as a chemical reaction catalyst, such that the third material is insoluble in the first developer containing the quaternary ammonium hydroxide; and removing the first intermediate structure and unconverted portions of the second intermediate structure using the quaternary ammonium hydroxide of the first developer to form a mandrel including the mandrel region of the third material, such that at least part of the mandrel has a critical dimension corresponding to the first depth.

In accordance with an embodiment of the present disclosure, a method for forming a patterned mask can include: providing a first intermediate structure on a substrate, where the first intermediate structure includes a first material, where the first material includes a solubility shifting agent therein, and where the first material is soluble in a first developer containing a quaternary ammonium hydroxide in an aqueous solution, and insoluble in a second developer containing an organic solvent; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is soluble in the first developer containing the quaternary ammonium hydroxide and insoluble in the second developer containing the organic solvent; diffusing at least a catalyst portion of the solubility shifting agent from the first material into the first region of the second intermediate structure and chemically transforming the first region of the second intermediate structure to a mandrel region of a third material to a first depth into the second intermediate structure using the catalyst portion of the solubility shifting agent as a chemical reaction catalyst, such that the third material is insoluble in the first developer containing the quaternary ammonium hydroxide and soluble in the second developer containing the organic solvent; and removing the first intermediate structure and unconverted portions of the second intermediate structure using the quaternary ammonium hydroxide of the first developer to form a mandrel including the mandrel region of the third material, such that at least part of the mandrel has a critical dimension corresponding to the first depth.

In accordance with an embodiment of the present disclosure, a method for forming a patterned mask can include: providing a first patterned photoresist layer on a substrate, where the first patterned photoresist layer includes a first material, where the first material includes a solubility shifting agent therein, and where the first material is soluble in a first developer containing a quaternary ammonium hydroxide in an aqueous solution; depositing a first overcoat layer over the first patterned photoresist layer and the substrate, where the first overcoat layer includes a second material, where the second material includes a first polymer and a first reactant, where the second material is soluble in the first developer containing the quaternary ammonium hydroxide; diffusing at least a catalyst portion of the solubility shifting agent from the first patterned photoresist layer into first regions of the first overcoat layer, where the first regions are adjacent the first patterned photoresist layer, and chemically transforming the first regions of the first overcoat layer to mandrel regions of a third material to a first depth into the first overcoat layer using the catalyst portion of the solubility shifting agent as a chemical reaction catalyst, such that the third material is insoluble in the first developer containing the quaternary ammonium hydroxide; and removing the first patterned photoresist layer of the first material and unconverted portions of the first overcoat layer of the second material using the quaternary ammonium hydroxide of the first developer to form a mandrel pattern of mandrels including the mandrel regions of the third material, such that at least part of the mandrels has a critical dimension corresponding to the first depth.

In accordance with an embodiment of the present disclosure, a method for forming a patterned mask can include: providing a first patterned photoresist layer on a substrate, where the first patterned photoresist layer includes a first material, where the first material includes a first polymer and a first reactant, and where the first material is soluble in a first developer containing a quaternary ammonium hydroxide in an aqueous solution; depositing a first overcoat layer over the first patterned photoresist layer and the substrate, where the first overcoat layer includes a second material, where the second material includes a solubility shifting agent therein, and where the second material is soluble in the first developer containing the quaternary ammonium hydroxide; diffusing at least a catalyst portion of the solubility shifting agent from the first overcoat layer into outer regions of the first patterned photoresist layer and chemically transforming the outer regions of the first patterned photoresist layer to mandrel regions of a third material to a first depth into the first patterned photoresist layer using the catalyst portion of the solubility shifting agent as a chemical reaction catalyst, such that the third material is insoluble in the first developer containing the quaternary ammonium hydroxide; and removing the first patterned photoresist layer of the first material and unconverted portions of the first overcoat layer of the second material using the quaternary ammonium hydroxide of the first developer to form a mandrel pattern of mandrels including the mandrel regions of the third material, such that at least part of the mandrels has a critical dimension corresponding to the first depth.

In accordance with an embodiment of the present disclosure, a chemical composition for a photoresist material configured to be used in semiconductor manufacturing can include a chemically amplified photosensitive composition including a first polymer, a first reactant, a photoacid generator, and a solvent, wherein the chemically amplified photosensitive composition is configured such that after deposition and before exposure to radiation, the chemically amplified photosensitive composition is insoluble in a first developer containing an organic solvent and is soluble in a second developer containing a quaternary ammonium hydroxide in an aqueous solution. The chemical composition can further include an additional optional component, such as a quencher.

In accordance with an embodiment of the present disclosure, a chemical composition for an overcoat material configured to be used in semiconductor manufacturing (e.g., anti-spacer process flow) can comprise a starting overcoat chemical composition that includes a first polymer, a first reactant, a solvent, and may also contain additional optional components, without a PAG, TAG, or SSA, wherein the starting overcoat chemical composition is configured such that after deposition to form an overcoat layer, the overcoat layer is insoluble in a developer containing an organic solvent and is soluble in a developer containing a quaternary ammonium hydroxide in an aqueous solution. The overcoat chemical composition can further include an additional optional component, such as a quencher.

In accordance with an embodiment of the present disclosure, a pattern forming method can include: a) providing a semiconductor substrate; b) forming a photoresist film comprising coating the semiconductor substrate with a chemically amplified photosensitive composition including a first polymer, a first reactant, a photoacid generator, and a solvent, wherein the chemically amplified photosensitive composition is configured such that after deposition and before exposure to radiation, the chemically amplified photosensitive composition is insoluble in a first developer containing an organic solvent and is soluble in a second developer containing a quaternary ammonium hydroxide in an aqueous solution; c) exposing the resist film with actinic rays or electromagnetic radiation; and d) developing the resist film with a developer.

In the pattern forming method, the developer can include an organic solvent.

In the pattern forming method, the developer can include propylene glycol methyl ether acetate, propylene glycol methyl ether, N-butyl acetate, 2-heptanone, methyl isobutyl carbinol, isoamyl alcohol, n-butanol, isoamyl ether, cyclohexanone, ethyl lactate, methyl isobutyl ketone, or methyl 2-hydroxyisobutyrate.

### BRIEF DESCRIPTION OF THE DRAWINGS

For a more complete understanding of example embodiments of the present disclosure, and the advantages thereof, reference is now made to the following descriptions taken in conjunction with the accompanying drawings, in which:

FIGS. 1A to 1C are cross-section views illustrating intermediate structures in a method for forming a patterned mask according to an embodiment of the present disclosure;

FIG. 1D is a cross-section view illustrating an anti-spacer patterned mask formed using the method portrayed in FIGS. 1A to 1C, according to an embodiment of the present disclosure;

FIG. 1E is a cross-section view illustrating a patterned mask formed using the method portrayed in FIGS. 1A to 1C, according to an embodiment of the present disclosure;

FIGS. 2A to 2E are cross-section views illustrating intermediate structures in a method for forming an anti-spacer patterned mask according to an embodiment of the present disclosure;

FIGS. 3A to 3E are cross-section views illustrating intermediate structures in a method for forming an anti-spacer patterned mask according to an embodiment of the present disclosure;

FIG. 3F is a cross-section view illustrating a deposition of an inventive chemical composition of a photoresist material configured for use in semiconductor manufacturing according to an embodiment of the present disclosure;

FIG. 4 is a flowchart illustrating a method for forming a patterned mask according to an embodiment of the present disclosure;

FIG. 5 is a flowchart illustrating a method for forming a patterned mask according to an embodiment of the present disclosure;

FIG. 6 is a flowchart illustrating a method for forming a patterned mask according to an embodiment of the present disclosure;

FIG. 7 is a flowchart illustrating a method for forming an anti-spacer patterned mask according to an embodiment of the present disclosure;

FIG. 8 is a flowchart illustrating a method for forming an anti-spacer patterned mask according to an embodiment of the present disclosure;

FIG. 9 is a flowchart illustrating a method for forming a patterned mask according to an embodiment of the present disclosure; and

FIG. 10 is a flowchart illustrating a method for forming a patterned mask according to an embodiment of the present disclosure.

### DETAILED DESCRIPTION OF ILLUSTRATIVE EMBODIMENTS

Referring now to the drawings, in which like reference numbers can be used herein to designate like or similar elements throughout the various views, illustrative and example embodiments are shown and described. The figures are not drawn to scale, and in some instances the drawings are exaggerated or simplified in places for illustrative purposes, including relative thicknesses and/or widths of layers and structures shown in the drawings. One of ordinary skill in the art can appreciate many possible applications and variations for other embodiments based on the following illustrative and example embodiments provided in the present disclosure.

In the present disclosure, terms such as “first”, “second”, “third”, “fourth”, and the like, can be used to describe various components, but the components are not necessarily limited by such terms, for example, regarding order, sequence, importance, or number of such components possible in an embodiment. Such terms can be used merely for the purpose of distinguishing one component from other components in a given embodiment or group of embodiments. Because semiconductor geometries and sizes can be so extremely small (e.g., on the order of 1 to 5 nm), the terms “film” and “layer” may be used interchangeably herein.

Ever continuous scaling can require improved patterning resolution. One approach is spacer technology to define a sub-resolution line feature via atomic layer deposition (ALD). One challenge, however, is that if the opposite tone feature is desired, using spacer techniques can involve a complex succession of operations, including over-coating with another material (an “overcoat”), using the spacer features as mandrels, chemical mechanical planarization (CMP), and reactive ion etch (RIE) to exhume the spacer material leaving a narrow trench, which can be costly. In such cases, spacer techniques can involve a complex and costly succession of steps, including over-coating with another material (an “overcoat”) using the spacer features as mandrels, chemical-mechanical planarization (CMP) to reveal the spacer features, and reactive ion etching (RIE) to remove the spacer material, leaving a narrow trench.

Anti-spacer technology is an alternate, self-aligned approach that can use the diffusion length of a reactive species across a boundary between an overcoat and an adjacent layer to define a critical dimension (CD), creating a narrow trench around the features of that adjacent layer after development of the overcoat or creating a narrow trench into the features of that adjacent layer after development of the diffusion changed regions. When generation of the reactive species is controlled spatially via exposure through a mask, finer features can be formed, such as a narrow slot contact. The CD itself can be tuned based on the physical and chemical properties of the reactive species (e.g., its molecular weight and affinity for interactions with the host material) and by modifying the bake temperature and bake time in a post exposure bake (PEB). As a result, anti-spacer techniques can enable patterning narrow slot-contact features at dimensions beyond the reach of advanced lithographic capabilities.

In some recent methods of forming an anti-spacer mask, an initial material property is that being a so-called “protected” polymer that is not soluble in a typically-used developer, such as a quaternary ammonium hydroxide in an aqueous solution, or more specifically such as TetraMethylAmmonium Hydroxide (TMAH), for example. And then after a chemical transformation of the initial material to a given depth to form an anti-spacer region of a second material that is soluble in TMAH, such that the second material is a so-called “unprotected” polymer (with respect to TMAH). Next, when the wafer is developed using TMAH, the anti-spacer region can be removed to form openings, such as narrow line cuts, to form an anti-spacer mask. Accordingly, such recent methods of forming an anti-spacer mask typically start with a “protected” polymer (with respect to TMAH) that is converted to an “unprotected” polymer (with respect to TMAH) so that a development operation using TMAH as the developer will remove or etch away the “unprotected” polymer regions.

In an embodiment of the present disclosure, a method of forming an anti-spacer mask can do the opposite, that is, starting with an “unprotected” polymer (with respect to a developer containing a quaternary ammonium hydroxide in an aqueous solution, such as TMAH, for example) that is converted to a “protected” polymer (with respect to TMAH) so that a development operation using a developer including an organic solvent (rather than TMAH) will remove or etch away the converted or “protected” polymer. Alternatively, in an embodiment of the present disclosure, a method of forming pillars or mandrels of a mask, or an intermediate mask structure, can start with an “unprotected” polymer (with respect to TMAH) that is converted to a “protected” polymer (with respect to TMAH) so that a development operation using TMAH as the developer, for example, will remove or etch away the “unprotected” polymer leaving remaining pillars or mandrels. Such embodiments will be described in much greater detail below.

In a method of forming an anti-spacer pattern or mask according to an embodiment of the present disclosure, an advantage of removing or etching away an anti-spacer region (or converted region) to define a narrow line using an organic solvent, rather than using a quaternary ammonium hydroxide in an aqueous solution, is that an organic solvent (as a developer) has much less surface tension compared to water (or a developer of a quaternary ammonium hydroxide in an aqueous solution, such as TMAH). Having less surface tension can enable the developer to better penetrate into and enter into smaller vias, holes, and trenches, as compared to water. This can enable vias, holes, and trenches having smaller critical dimensions to be formed in an anti-spacer pattern/mask, which can thereby enable further scale to smaller sizes and geometries to progress further beyond current limits of photolithography (e.g., sub-resolution lithography, sub-lithography patterning, sub-wavelength lithography, sub-diffraction lithography, self-aligned double patterning (SADP)). Additionally, this high surface tension can cause pattern collapse as the features are pulled together while the aqueous developer or rinse is drying. This advantage of less surface tension for an organic solvent can be a major or main motivation to change materials and/or developers for a method of forming an anti-spacer pattern/mask, in accordance with an embodiment of the present disclosure.

In some embodiments of the present disclosure, a method for forming a patterned mask can include: providing a first intermediate structure on a substrate, where the first intermediate structure includes a first material, where the first material includes a solubility shifting agent therein, and where the first material is insoluble in a first developer containing an organic solvent; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent; and diffusing at least a catalyst portion of the solubility shifting agent from the first material into the first regions of the second intermediate structure and chemically transforming the first regions of the second intermediate structure to converted regions of a third material to a first depth into the second intermediate structure using the catalyst portion of the solubility shifting agent as a chemical reaction catalyst, such that the third material is soluble in the first developer containing the organic solvent.

In some embodiments of the present disclosure, a method can further include removing the converted regions using the organic solvent of the first developer to form an anti-spacer pattern including remaining portions of the first intermediate structure and the second intermediate structure having openings to the substrate corresponding to the converted regions and where at least part of the openings has a critical dimension corresponding to the first depth.

In some embodiments of the present disclosure, where the first material and the second material are soluble in a second developer containing a quaternary ammonium hydroxide in an aqueous solution, and where the third material is insoluble in the second developer containing the quaternary ammonium hydroxide, and a method can further include removing the first intermediate structure and unconverted portions of the second intermediate structure using the quaternary ammonium hydroxide of the second developer to form a mandrel pattern of mandrels including the converted regions of the third material, such that at least part of the mandrels has a critical dimension corresponding to the first depth.

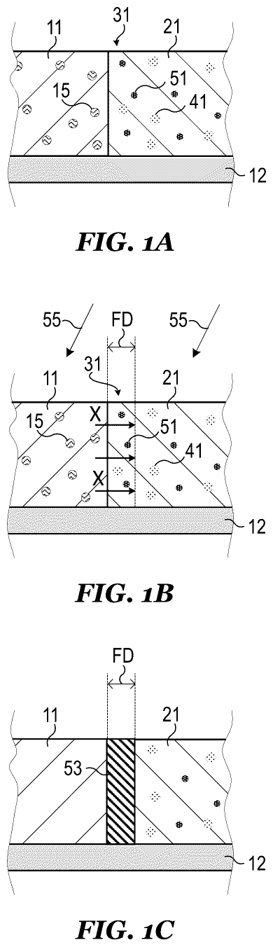

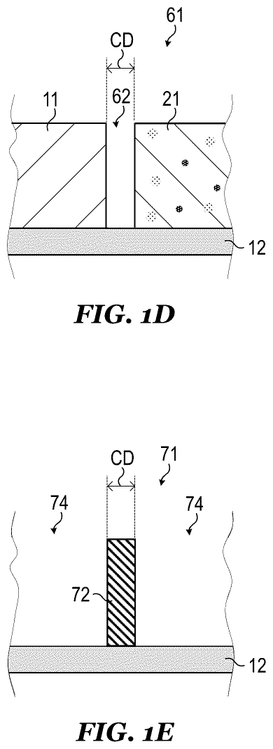

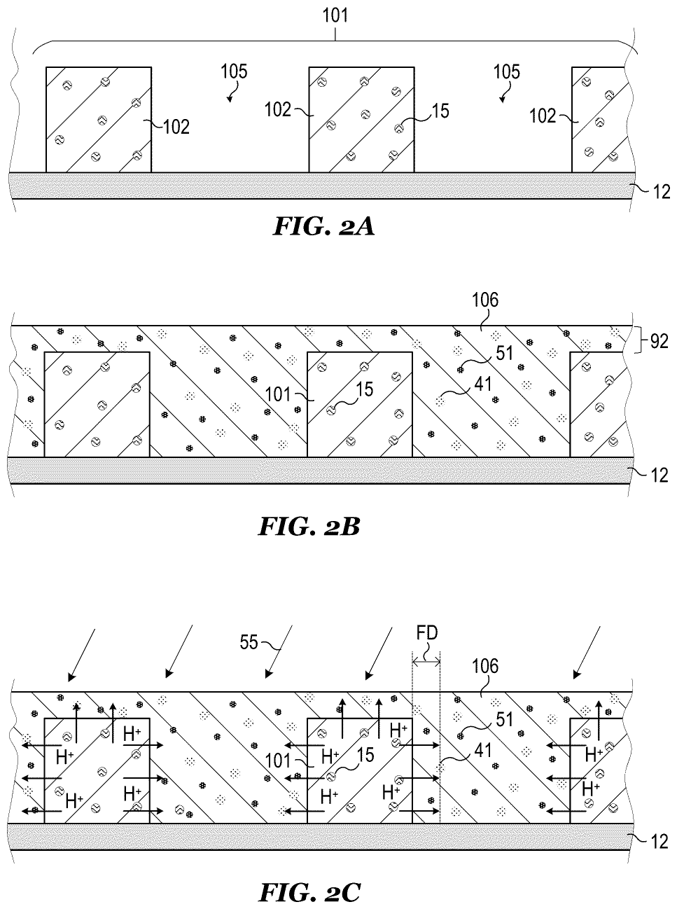

Some example embodiments of the present disclosure are described in detail with reference to FIGS. 1A to 10.

FIGS. 1A to 1C are cross-section views illustrating intermediate structures in a method for forming a patterned mask according to an embodiment of the present disclosure. Referring to FIG. 1A, a first intermediate structure 11 can be provided on a substrate 12. The first intermediate structure 11 can include a first material, and the first material can include a solubility shifting agent (SSA) 15 therein. In some embodiments, the SSA 15 can be formed in situ during the deposition of the first material, during the formation of the first intermediate structure 11. In such case, the SSA 15 can be evenly distributed throughout the first material, for example, but not necessarily. In some embodiments, the first intermediate structure 11 of the first material can be deposited without the SSA and the SSA 15 can be put into the first material of the first intermediate structure 11 thereafter. For example, in some embodiments, the SSA 15 can be implanted or diffused into the first material of the first intermediate structure 11. In some embodiments, the SSA 15 can be put into only or mostly in outer regions of the first intermediate structure 11, rather than being in the entirety of the first intermediate structure 11 and/or rather than being even distributed in the first intermediate structure 11, for example. The first material of the first intermediate structure 11 can be insoluble in a first developer containing an organic solvent, soluble in a second developer containing a quaternary ammonium hydroxide in an aqueous solution (e.g., TMAH), or a combination thereof.

Referring to FIG. 1A, a second intermediate structure 21 can be provided on the substrate 12. The second intermediate structure 21 can include a second material. A first region 31 of the second intermediate structure 21 including the second material can be adjacent and in direct physical contact with the first material of the first intermediate structure 11. In some embodiments, there can be one or more intervening layers (not shown in the drawings) between the first intermediate structure 11 and the second intermediate structure 21 at the first region 31 provided that certain materials can diffuse through such one or more intervening layers (diffusion discussed next). The second material can include a first polymer 41 and a first reactant 51, such that the second material is insoluble in a first developer containing an organic solvent, soluble in a second developer containing a quaternary ammonium hydroxide in an aqueous solution (e.g., TMAH), or a combination thereof. In some embodiments, the first polymer 41 and/or the first reactant 51 can be formed in situ during the deposition of the second material, during the formation of the second intermediate structure 21. In such case, the first polymer 41 and/or the first reactant 51 can be evenly distributed throughout the second material, for example, but not necessarily.

In the present disclosure, for an embodiment, the term “substrate” (e.g., substrate 12) can be used generally and as a shorthand description for an underlying structure that can include any combination of layers, materials, structures, devices, and a wafer of any suitable structure. For example, the substrate 12 of an embodiment can include one or more bottom anti-reflective coating (BARC)layers, one or more developable BARC (dBARC)layers, one or more etch stop layers, one or more hard mask layers, one or more dielectric layers, one or more intermetal dielectric layers, one or more conductive lines/layers/interconnects, one or more transistor structures, one or more capacitor structures, one or more resistor structures, one or more inductor structures, one or more memory cells, or any combination thereof.

In some embodiments, the second intermediate structure 21 of the second material can be deposited without the first reactant 51 and the first reactant 51 can be put into the second material of the second intermediate structure 21 thereafter. For example, in some embodiments, the first reactant 51 can be implanted or diffused into the second material of the second intermediate structure 21. In some embodiments, the first reactant 51 can be put into only or mostly in outer regions of the second intermediate structure 21, rather than being in the entirety of the second intermediate structure 21 and/or rather than being even distributed in the second intermediate structure 21, for example.

Referring to FIGS. 1B and 1C, at least a catalyst portion X (e.g., an acid) of the SSA 15 from the first material (from the first intermediate structure 11) can be diffused into the first region 31 of the second intermediate structure 21 and chemically transform the first region 31 of the second intermediate structure 21 to a converted region 53 of a third material to a first depth FD into the second intermediate structure 21 using the catalyst portion X of/from the SSA 15 as a chemical reaction catalyst, such that the third material is soluble in the first developer containing the organic solvent.

In the drawings for the present disclosure (e.g., FIGS. 1B, 2C, and 3C), for simplification of the drawings, “X” can be used as shorthand notation to denote and represent a catalyst, which in some embodiments can be an acid shown as “H⁺” as an example, that is being diffused, such as an acid that donates a proton (e.g., H⁺) in a chemical reaction (e.g., as a catalyst). However, an acid being diffused in an embodiment of the present disclosure is not necessarily limited to one that provides a hydrogen ion. For example, the catalyst in some embodiments can be a base. For example, “H⁺” may not necessarily accurately describe some acid species that can be used in an embodiment of the present disclosure, as can be apparent to one of ordinary skill in the art for which the present disclosure pertains. Thus, the use of “X” can be as a reference in the drawings for the catalyst, and the use of “H⁺” as an example for representing an acid in some example embodiments, are not intended to necessarily limit the chemical makeup or chemical action of the catalyst in an embodiment.

While describing the example embodiments of the present disclosure, the term “solubility shifting agent” or “SSA” can refer to a substance in a general sense that if not already a catalyst agent itself, it can generate and/or can transform (e.g., by heat and/or certain radiation of light) to a catalyst agent and/or constituent parts that includes a catalyst agent that can be used in a chemical reaction to shift or change a solubility property of a material.

In an embodiment, an SSA 15 is used in an embodiment can include an agent-generating ingredient that, in response to a suitable agent-activation trigger (e.g., heat and/or radiation), generates a solubility-changing chemical (e.g., an acid). Example agent-generating ingredients can include a thermal-acid generator (TAG) that is configured to generate an acid in response to heat or a photo-acid generator (PAG) that is configured to generate an acid in response to actinic radiation.

In an embodiment, the first polymer 41 and the first reactant 51 can be at stochiometric state at room temperature, such that they remain separate. In an embodiment, the catalyst of/from the SSA 15 can cause the chemical reaction between the first polymer 41 and the first reactant 51 to occur at a lower temperature, such as in a temperature range of 70° C. to 120° C., depending on the strength of an acid of/from the SSA 15, the choice of monomer/polymer, and the choice of the added reactant molecule, as compared to a temperature at which can be required to cause the first polymer 41 and the first reactant 51 to combine/convert to another material without the catalyst (without a certain acid present), such as in a temperature range of more than 150° C., or more than 180° C. in some cases, which can be outside the thermal budget for the materials used as photoresist, for example. Also, by limiting the diffusion depth (e.g., the first depth FD) of the catalyst (e.g., acid of/from the SSA 15), a controlled region (e.g., the converted region 53) can be converted at a relatively lower temperature while the remainder of the second intermediate structure 21 not having the catalyst diffused therein remains unconverted, in accordance with an embodiment of the present disclosure.

For example, the chemically transforming of the first region 31 of the second intermediate structure 21 can include diffusing acid from the first intermediate structure 11 into the first region 31 of the second intermediate structure 21 to increase solubility or change/shift solubility of the first region 31 for a given developer (e.g., the first developer containing an organic solvent) such that the first region 31 of the second intermediate structure 21 become the converted region 53 of a third/different material.

For example, the first intermediate structure 11 can include a free acid as an SSA 15. During a baking operation, the free acid (represented as “X” in FIG. 1B) can diffuse into perimeter portions (first region 31) of the second intermediate structure 21 (i.e., regions adjacent and/or in physical contact with the first material of the first intermediate structure 11 including the SSA 15) and can cause the perimeter portions of the second intermediate structure 21 to become soluble in a given developer, where the original material (untransformed remaining portions) of the second intermediate structure 21 is not soluble or is orders of magnitude less soluble to the given developer.

As another example, the first intermediate structure 11 can include a TAG as an agent-generating ingredient for the SSA 15. Baking the wafer can cause the TAG to generate a solubility-changing agent (e.g., acid as a catalyst, represented as “X” in FIG. B), which can be referred to as activating the acid, and the baking can also cause the generated solubility-changing agent to diffuse into perimeter portions (first region 31) of the second intermediate structure 21 and can cause the first region 31 of the second intermediate structure 21 to become soluble in a given developer, where the original material (untransformed remaining portions) of the second intermediate structure 21 is not soluble or is orders of magnitude less soluble to the given developer.

As another example, the first intermediate structure 11 can include a PAG as an agent-generating ingredient for the SSA 15. The first intermediate structure 11 can be exposed to a radiation (e.g., actinic radiation) that can be performed prior to baking the wafer. Such exposure to radiation can cause the PAG to generate a solubility-changing agent (e.g., acid as a catalyst, represented as “X” in FIG. B), which can be referred to as activating the acid. Then, baking of the wafer can cause the generated solubility-changing agent to diffuse into perimeter portions (first region 31) of the second intermediate structure 21 and can cause the first region 31 of the second intermediate structure 21 to become soluble in a given developer, where the original material (untransformed remaining portions) of the second intermediate structure 21 is not soluble or is orders of magnitude less soluble to the given developer.

In an embodiment, a baking process for forming the converted region 53 of the third material can be a thermal process that is performed by heating the wafer in a process chamber to a temperature between 50° C. and 250° C., for example, or between 6° C. and 140° C. in certain embodiments, in vacuum or under a gas flow. In a particular example, the wafer can be baked for a duration in a range from 1 to 3 minutes. The bake conditions can be selected to promote the diffusion of the solubility-changing agent (and possibly generation of the solubility-changing agent from an agent generating ingredient of the SSA 15 in the first intermediate structure 11 and/or in the second intermediate structure 21, if applicable) and associated change in solubility of the perimeter regions (first region 31) of the second intermediate structure 21 to a target first depth FD (see, e.g., FIGS. 1B and 1C). The first depth FD can be tuned by parameters of the baking process (such as, for example, a bake temperature and a bake duration) and material parameters (such as, for example, a polymer composition of the second intermediate structure 21, and an acid composition and an acid concentration from the SSA 15 in the first intermediate structure 11). Some example materials that can be used for the SSA 15 or generated from the SSA 15 as a catalyst for the chemical reaction to shift/change the solubility of the first region 31 to the converted region 53 of the third material in an embodiment will be described later in the present disclosure.

In FIG. 1B, the energy from the heat and/or radiation used in the process of chemically transforming the first region 31 to the converted region 53 of the third material is illustrated generally by downward pointing arrows 55. However, as can be understood by one of ordinary skill in the art pertaining to such process, the direction(s) and vector(s) of the heat and/or radiation can be from any suitable direction(s)/vector(s) and from any suitable source of provided in a given tool. Hence, the downward pointing arrows 55 of FIG. 1B can be merely illustrative.

In the present disclosure, the terms “soluble” and “insoluble” are used in a relative sense, not in an absolute sense. That is, the term “insoluble” as used herein refers to one subject material being dissolved or removed much faster and much more effectively compared to another adjacent non-subject material, such as an order of magnitude or more faster and more effectively, and not to necessarily be that the other adjacent non-subject material experiences no dissolving or removal, but rather that the subject material is removed so much faster and more effectively that the subject material can be dissolved and removed sufficiently or to its full extent while only a small amount or even only a negligible amount of the other adjacent non-subject material is dissolved and removed, such that most of or almost all of the other adjacent non-subject material at the stopping point of the dissolving and removing of the subject material, as can be apparent to one of ordinary skill in the art pertaining to the present disclosure.

FIG. 1D is a cross-section view illustrating an anti-spacer patterned mask 61 formed using the method portrayed in FIGS. 1A to 1C, according to an embodiment of the present disclosure. To form the anti-spacer patterned mask 61 shown in FIG. 1D, the converted region 53 of the third material can be removed using a first developer containing an organic solvent to form an opening 62 to the substrate 12 that is bounded by and defined by remaining portions (i.e., portions unconverted by the catalyst of/from SSA 15) of the second intermediate structure 21 and remaining portions (i.e., portions unconverted by the catalyst of/from SSA 15) of the first intermediate structure 11. Because the opening 62 can be formed by the removal of the converted region 53 of the third material, and because the converted region 53 can have dimensions defined by or corresponding to the first depth FD for which the catalyst of/from the SSA 15 diffused into the first region 31 of the second intermediate structure 21, at least part of the opening 62 can have a critical dimension CD corresponding to the first depth FD. The critical dimension CD is not necessarily equal to the first depth FD in some embodiments, but can be derived from and dependent upon the first depth FD for which most of or all of the catalyst of/from the SSA 15 diffused into the second intermediate structure 21. Thus, a critical dimension CD of an opening 62 can be adjusted, tuned, and specified based on parameters (e.g., temperature, bake time, radiation energy, exposure time, etc.) for the process of diffusing the catalyst of/from the SSA 15 and/or the process of causing the chemical reaction to form the third material of the converted region 53, as well as other factors, such as the choice of the substance for the catalyst of/from the SSA 15, the first material of the first intermediate structure 11 (e.g., choice of photoresist material(s) and/or other additives), the choice of the first polymer 41 of the second intermediate structure 21, the choice of the first reactant 51 of the second intermediate structure 21, other additives/substances present also in the second intermediate structure 21, or any suitable combination thereof.

Although only one opening 62 is shown in FIG. 1D for purposes of simplified illustration, it can be apparent to one of ordinary skill in the art that in an embodiment there can numerous openings for the anti-spacer patterned mask 61 of various shapes and sizes across a given die and across a wafer while implementing an embodiment of the present disclosure.

FIG. 1E is a cross-section view illustrating a patterned mask 71 formed using the method portrayed in FIGS. 1A to 1C, according to an embodiment of the present disclosure. To form the patterned mask 71 shown in FIG. 1E, unconverted portions (i.e., portions unconverted by the catalyst of/from SSA 15) of the first intermediate structure 11 and unconverted portions (i.e., portions unconverted by the catalyst of/from SSA 15) of the second intermediate structure 21 can be removed using a second developer containing a quaternary ammonium hydroxide, such as TMAH, to form a mandrel 72 of the converted region 53 of the third material, such that at least part of the mandrel 72 has a critical dimension CD corresponding to the first depth FD. Openings 74 to the substrate 12 can be formed adjacent the mandrel 72 corresponding to the removed unconverted portions of the first intermediate structure 11 and the removed unconverted portions of the second intermediate structure 21.

Because the mandrel 72 can be formed by the remainder (non-removed, non-dissolved by the second developer, portions of the converted region 53) of the converted region 53 of the third material, and because the converted region 53 can have dimensions defined by or corresponding to the first depth FD for which the catalyst of/from the SSA 15 diffused into the first region 31 of the second intermediate structure 21, at least part of the mandrel 72 can have a critical dimension CD corresponding to the first depth FD. The critical dimension CD is not necessarily equal to the first depth FD in some embodiments, but can be derived from and dependent upon the first depth FD for which most of or all of the catalyst of/from the SSA 15 diffused into the second intermediate structure 21. Thus, a critical dimension CD of a mandrel 72 can be adjusted, tuned, and specified based on parameters (e.g., temperature, bake time, radiation energy, exposure time, etc.) for the process of diffusing the catalyst of/from the SSA 15 and/or the process of causing the chemical reaction to form the third material of the converted region 53, as well as other factors, such as the choice of the substance for the catalyst of/from the SSA 15, the first material of the first intermediate structure 11 (e.g., choice of photoresist material(s) and/or other additives), the choice of the first polymer 41 of the second intermediate structure 21, the choice of the first reactant 51 of the second intermediate structure 21, other additives/substances present also in the second intermediate structure 21, or any suitable combination thereof.

Although only one mandrel 72 is shown in FIG. 1E for purposes of simplified illustration, it can be apparent to one of ordinary skill in the art that in an embodiment there can numerous mandrels for the patterned mask 71 of various shapes and sizes across a given die and across a wafer while implementing an embodiment of the present disclosure.

In an alternative embodiment, the first reactant can be diffused, rather than the SSA being diffused alone, to provide the elements of the first polymer, the first reactant, and the catalyst (e.g., from an SSA) together into a diffused region (to a diffusion depth FD) to chemically convert into the converted material with solubility in a developer containing an organic solvent.

Many example materials for an SSA 15, a first polymer 41, a first reactant 51, a third material of a converted region 53, a first developer, and a second developer, relating to the example embodiments of FIGS. 1A to 1E, will be described below in the present disclosure.

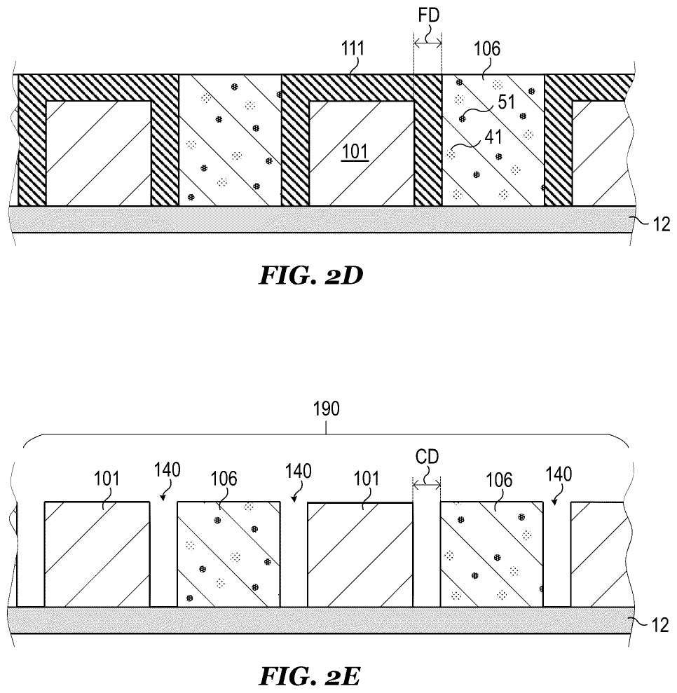

FIGS. 2A to 2E are cross-section views illustrating intermediate structures in a method for forming an anti-spacer patterned mask according to an embodiment of the present disclosure.

Referring to FIG. 2A, a first patterned photoresist layer 101 can be provided on a substrate 12. The first patterned photoresist layer 101 can have a pattern of mandrels 102 and openings 105 formed therein and opening to the substrate 12, for example, to form a relief pattern. The first patterned photoresist layer 101 can include a solubility shifting agent (SSA) 15 therein. The first patterned photoresist layer 101 can be insoluble in a first developer containing an organic solvent. The first patterned photoresist layer 101 can be formed using any suitable process, which will not be described in detail herein because there can be many different processes that can be used to create the first patterned photoresist layer 101 as can be apparent to one of ordinary skill in the art when implementing an embodiment of the present disclosure. For purposes of discussion of an embodiment of the present disclosure, the first patterned photoresist layer 101 can be considered a first intermediate structure, such as described as a first intermediate structure 11 with reference to FIG. 1A. Accordingly, the variations and description regarding the first intermediate structure 11 of FIGS. 1A to 1C can be applicable to the first patterned photoresist layer 101 of FIG. 2A, and thus will not be repeated here.

Referring to FIG. 2B, a first overcoat layer 106 can be deposited over the first patterned photoresist layer 101 and the substrate 12. The first overcoat layer 106 can include a first polymer 41 and a first reactant 51. The first overcoat layer 106 can be insoluble in a first developer containing an organic solvent. The first overcoat layer 106 can be deposited using any suitable process, such as spin-on coating/deposition, for example. The first overcoat layer 106 can have an overburden 92 deposited higher than a highest feature of the first patterned photoresist layer 101, which can be a normal occurrence when using a spin-on coating process for deposition, for example. In some embodiments, there may be no overburden 92 or very minimal (insubstantial) thickness of overburden 92.

The process for depositing the first overcoat layer 106 will not be described in detail here because there can be many different processes that can be used to create the first overcoat layer 106, as can be apparent to one of ordinary skill in the art when implementing an embodiment of the present disclosure. For purposes of discussion of an embodiment of the present disclosure, the first overcoat layer 106 including the first polymer 41 and the first reactant 51 can be considered a second intermediate structure, such as described as a second intermediate structure 21 with reference to FIG. 1A. Accordingly, the variations and description regarding the second intermediate structure 21 of FIGS. 1A to 1C can be applicable to the first overcoat layer 106 of FIG. 2B, and thus will not be repeated here.

Referring to FIGS. 2C and 2D, at least a catalyst portion (e.g., acid as a catalyst, represented as “H” in FIG. 2C) of/from the SSA 15 from the first patterned photoresist layer 101 can be diffused into first regions of the first overcoat layer 106. The first regions can be adjacent the first patterned photoresist layer 101, and can be regions immediately adjacent and having physical contact with the first patterned photoresist layer 101 into which the catalyst diffuses in the first overcoat layer 106 to a first depth FD. The first regions of the first overcoat layer 106 can be chemically transformed to anti-spacer regions 111 of a converted material to a first depth FD into the first overcoat layer 106 using the catalyst portion of the SSA 15 as a chemical reaction catalyst, such that the converted material is soluble in the first developer containing the organic solvent. For purposes of discussion of an embodiment of the present disclosure, the process of chemically transforming regions of the first overcoat layer 106 to anti-spacer regions 111 of a converted material can be considered as that of the converted region 53 with reference to FIGS. 1B and 1C. Accordingly, the variations and description regarding process and the converted region 53 of FIGS. 1B and 1C can be applicable to the anti-spacer regions 111 of a converted material and processes of making the anti-spacer regions 111 of a converted material of FIGS. 2C and 2D, and thus will not be repeated here.

Referring to FIG. 2E, the anti-spacer regions can be removed using an organic solvent of the first developer to form an anti-spacer pattern 190 include remaining portions (i.e., portions unconverted by the catalyst of/from SSA 15) of the first patterned photoresist layer 101 and remaining portions (i.e., portions unconverted by the catalyst of/from SSA 15) of the first overcoat layer 106 having openings 140 to the substrate 12 corresponding to the anti-spacer regions 111.

Because the openings 140 of the anti-spacer pattern 190 can be formed by the removal of the anti-spacer regions 111 of converted material, and because the anti-spacer regions 111 can have dimensions defined by or corresponding to the first depth FD for which the catalyst of/from the SSA 15 diffused into the first overcoat layer 106, at least part of the openings 140 can have a critical dimension CD corresponding to the first depth FD (e.g., compare FIGS. 2C to 2E). The critical dimension CD is not necessarily equal to the first depth FD in some embodiments, but can be derived from and dependent upon the first depth FD for which most of or all of the catalyst of/from the SSA 15 diffused into the first overcoat layer 106. Thus, a critical dimension CD of openings 140 can be adjusted, tuned, and specified based on parameters (e.g., temperature, bake time, radiation energy, exposure time, etc.) for the process of diffusing the catalyst of/from the SSA 15 and/or the process of causing the chemical reaction to form the anti-spacer regions 111 of converted material, as well as other factors, such as the choice of the substance for the catalyst of/from the SSA 15, the choice of the photoresist material of the first patterned photoresist layer 101 (e.g., choice of photoresist material(s) and/or other additives), the choice of the first polymer 41 of the first overcoat layer 106, the choice of the first reactant 51 of the first overcoat layer 106, other additives/substances present also in the first overcoat layer 106, or any suitable combination thereof, for example.

Although only similar or same openings 140 are shown in FIG. 2E for purposes of simplified illustration, it can be apparent to one of ordinary skill in the art that in an embodiment there can numerous different openings for the anti-spacer pattern 190 of various shapes and sizes across a given die and across a wafer while implementing an embodiment of the present disclosure.

Many example materials for the SSA 15, the first polymer 41, the first reactant 51, the converted material of the anti-spacer regions 111, and the first developer, relating to the example embodiment of FIGS. 2A to 2E, will be described below in the present disclosure.

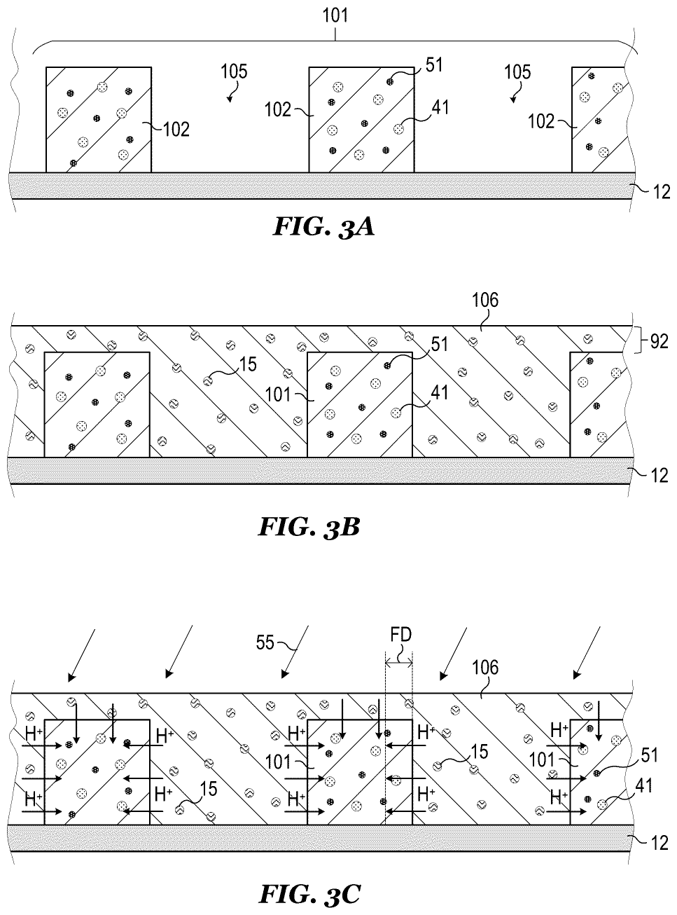

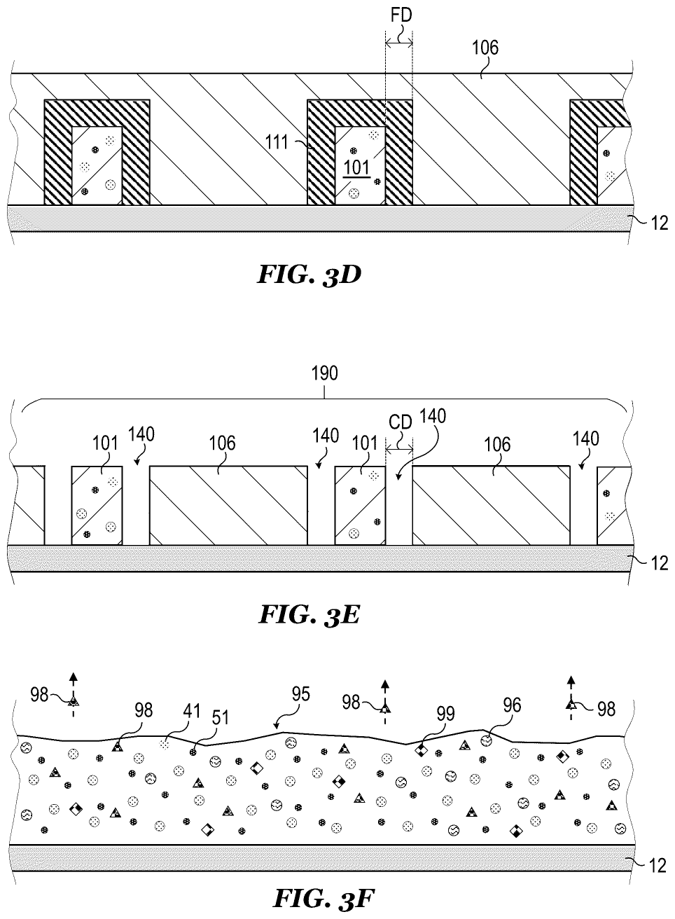

FIGS. 3A to 3E are cross-section views illustrating intermediate structures in a method for forming an anti-spacer patterned mask according to an embodiment of the present disclosure. The example embodiment illustrated in FIGS. 3A to 3A can be similar to the example embodiment described and illustrated in FIGS. 2A to 2E, except that first polymer 41 and the first reactant 51 are provided in the first patterned photoresist layer 101, and the SSA 15 is provided in the first overcoat layer 106. Accordingly, much description of the example embodiment of FIGS. 3A to 3E is not necessary as it would be redundant in some respects and/or apparent in view of the already provided description of the example embodiment of FIGS. 2A to 2E, as well as the example embodiment of FIGS. 1A to 1D.

Referring to FIG. 3A, a first patterned photoresist layer 101 can be provided on a substrate 12. The first patterned photoresist layer 101 can include a first polymer 41 and a first reactant 51. The first patterned photoresist layer 101 can be insoluble in a first developer containing an organic solvent. An example formation of the first patterned photoresist layer 101 of FIG. 3A will be discussed in more detail below relating to FIG. 3F while describing an inventive chemical composition for a photoresist material that can be used for forming a first patterned photoresist layer 101 of an embodiment of the present disclosure (e.g., as shown in FIG. 3A) or for forming a second intermediate structure 21 of an embodiment of the present disclosure (e.g., as shown in FIG. 1A).

In an alternative embodiment, the first reactant 51 can be implanted or diffused into the mandrels 102 of the first patterned photoresist layer 101, before or after the first patterned photoresist layer 101 is processed to form the openings 105. And in such example, the first reactant 51 can be implanted or diffused uniformly throughout the material, or into only outer regions of the mandrels 102, or into selected regions of the material (e.g., depending on a timing, depth, and angle of implantation/diffusion).

Referring to FIG. 3B, a first overcoat layer 106 can be deposited over the first patterned photoresist layer 101 and the substrate 12. The first overcoat layer 106 can include a solubility shifting agent (SSA) 15 therein. The first overcoat layer 106 can be insoluble in a first developer containing an organic solvent. The first overcoat layer 106 can have an overburden 92 deposited higher than a highest feature of the first patterned photoresist layer 101, and in some embodiments, there may be no overburden 92 or very minimal (insubstantial) thickness of overburden 92, for example.

For purposes of discussion of an embodiment of the present disclosure, the first overcoat layer 106 of FIG. 3B can be considered a first intermediate structure, such as described as a first intermediate structure 11 with reference to FIG. 1A. Accordingly, the variations and description regarding the first intermediate structure 11 of FIGS. 1A to 1C can be applicable to the first overcoat layer 106 of FIG. 3B, and thus will not be repeated here. For purposes of discussion of an embodiment of the present disclosure, the first patterned photoresist layer 101 including the first polymer 41 and the first reactant 51 of FIGS. 3A and 3B can be considered a second intermediate structure, such as described as a second intermediate structure 21 with reference to FIG. 1A. Accordingly, the variations and description regarding the second intermediate structure 21 of FIGS. 1A to 1C can be applicable to the first patterned photoresist layer 101 of FIGS. 3A and 3B, and thus will not be repeated here.

Referring to FIGS. 3C and 3D, at least a catalyst portion of the SSA 15 from the first overcoat layer 106 can be diffused into outer regions of the first patterned photoresist layer 101 and chemically transform the outer regions of the first patterned photoresist layer 101 to anti-spacer regions 111 of a converted material to a first depth FD into the first patterned photoresist layer 101 using the catalyst portion of the SSA 15 as a chemical reaction catalyst, such that the converted material of the anti-spacer regions 111 is soluble in the first developer containing the organic solvent. For purposes of discussion of an embodiment of the present disclosure, the process of chemically transforming outer regions of the first patterned photoresist layer 101 to anti-spacer regions 111 of a converted material can be considered as that of the converted region 53 with reference to FIGS. 1B and 1C. Accordingly, the variations and description regarding process and the converted region 53 of FIGS. 1B and 1C can be applicable to the anti-spacer regions 111 of a converted material and processes of making the anti-spacer regions 111 of a converted material of FIGS. 3C and 3D, and thus will not be repeated here.

Referring to FIG. 3E, the anti-spacer regions 111 can be removed using the organic solvent of the first developer to form an anti-spacer pattern 190 including remaining portions (i.e., portions unconverted by the catalyst of/from SSA 15) of the first overcoat layer 106 and remaining portions (i.e., portions unconverted by the catalyst of/from SSA 15) of the first patterned photoresist layer 101 having openings 140 to the substrate 12 corresponding to the anti-spacer regions 111. At least part of the openings 140 can have a critical dimension CD corresponding to the first depth FD, for example.

Many example materials for the SSA 15, the first polymer 41, the first reactant 51, the converted material of the anti-spacer regions 111, and the first developer, relating to the example embodiment of FIGS. 3A to 3E, will be described below in the present disclosure.

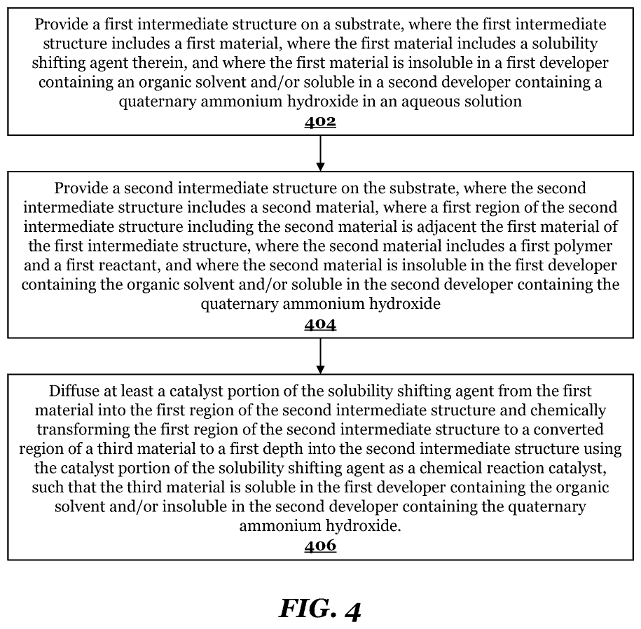

FIGS. 4 to 10 provide some example flowcharts illustrating some example methods that can be used for making the example embodiments described above and shown in FIGS. 1A to 3E, as well as other embodiments.

FIG. 4 is a flowchart illustrating a method for forming a patterned mask according to an embodiment of the present disclosure. In a method for forming a patterned mask, the method can include providing a first intermediate structure on a substrate, where the first intermediate structure includes a first material, where the first material includes a solubility shifting agent therein, and where the first material is insoluble in a first developer containing an organic solvent and/or soluble in a second developer containing a quaternary ammonium hydroxide in an aqueous solution (box 402).

In a method for forming a patterned mask, the method can include providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent and/or soluble in the second developer containing the quaternary ammonium hydroxide (box 404).

In a method for forming a patterned mask, the method can include diffusing at least a catalyst portion of the solubility shifting agent from the first material into the first region of the second intermediate structure and chemically transforming the first region of the second intermediate structure to a converted region of a third material to a first depth into the second intermediate structure using the catalyst portion of the solubility shifting agent as a chemical reaction catalyst, such that the third material is soluble in the first developer containing the organic solvent and/or insoluble in the second developer containing the quaternary ammonium hydroxide (box 406).

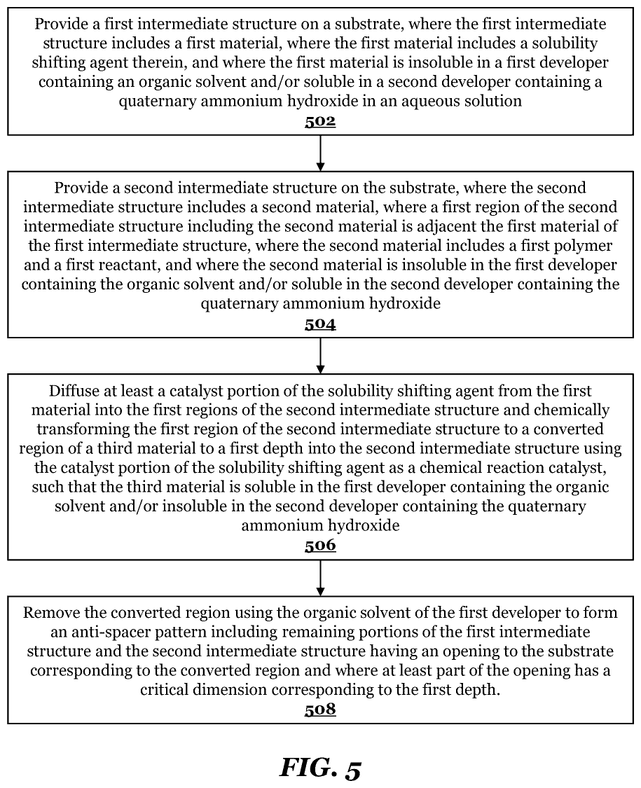

FIG. 5 is a flowchart illustrating a method for forming a patterned mask according to an embodiment of the present disclosure. In a method for forming a patterned mask, the method can include providing a first intermediate structure on a substrate, where the first intermediate structure includes a first material, where the first material includes a solubility shifting agent therein, and where the first material is insoluble in a first developer containing an organic solvent and/or soluble in a second developer containing a quaternary ammonium hydroxide in an aqueous solution (box 502).

In a method for forming a patterned mask, the method can include providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent and/or soluble in the second developer containing the quaternary ammonium hydroxide (box 504).

In a method for forming a patterned mask, the method can include diffusing at least a catalyst portion of the solubility shifting agent from the first material into the first regions of the second intermediate structure and chemically transforming the first region of the second intermediate structure to a converted region of a third material to a first depth into the second intermediate structure using the catalyst portion of the solubility shifting agent as a chemical reaction catalyst, such that the third material is soluble in the first developer containing the organic solvent and/or insoluble in the second developer containing the quaternary ammonium hydroxide (box 506).

In a method for forming a patterned mask, the method can include removing the converted region using the organic solvent of the first developer to form an anti-spacer pattern including remaining portions of the first intermediate structure and the second intermediate structure having an opening to the substrate corresponding to the converted region and where at least part of the opening has a critical dimension corresponding to the first depth (box 508).

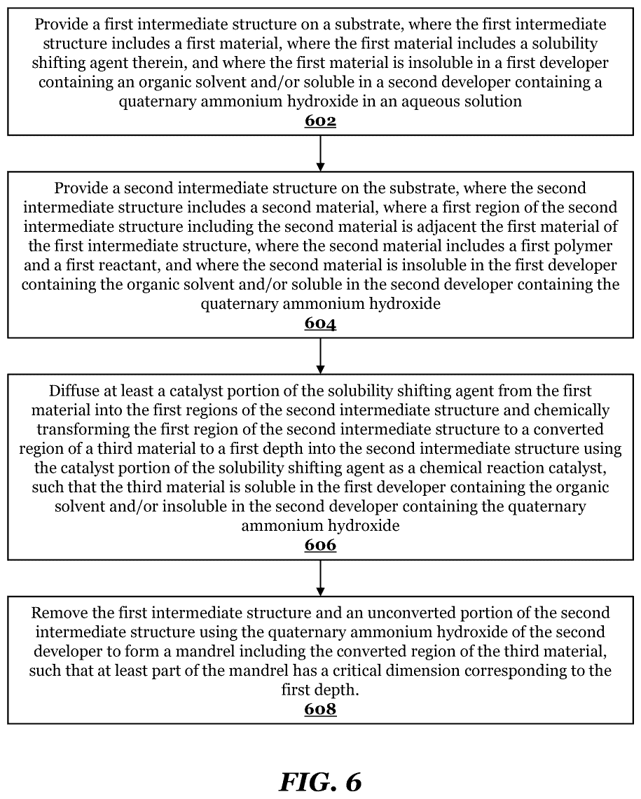

FIG. 6 is a flowchart illustrating a method for forming a patterned mask according to an embodiment of the present disclosure. In a method for forming a patterned mask, the method can include providing a first intermediate structure on a substrate, where the first intermediate structure includes a first material, where the first material includes a solubility shifting agent therein, and where the first material is insoluble in a first developer containing an organic solvent and/or soluble in a second developer containing a quaternary ammonium hydroxide in an aqueous solution (box 602).

In a method for forming a patterned mask, the method can include providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent and/or soluble in the second developer containing the quaternary ammonium hydroxide (box 604).

In a method for forming a patterned mask, the method can include diffusing at least a catalyst portion of the solubility shifting agent from the first material into the first regions of the second intermediate structure and chemically transforming the first region of the second intermediate structure to a converted region of a third material to a first depth into the second intermediate structure using the catalyst portion of the solubility shifting agent as a chemical reaction catalyst, such that the third material is soluble in the first developer containing the organic solvent and/or insoluble in the second developer containing the quaternary ammonium hydroxide (box 606).

In a method for forming a patterned mask, the method can include removing the first intermediate structure and an unconverted portion of the second intermediate structure using the quaternary ammonium hydroxide of the second developer to form a mandrel including the converted region of the third material, such that at least part of the mandrel has a critical dimension corresponding to the first depth (box 608).

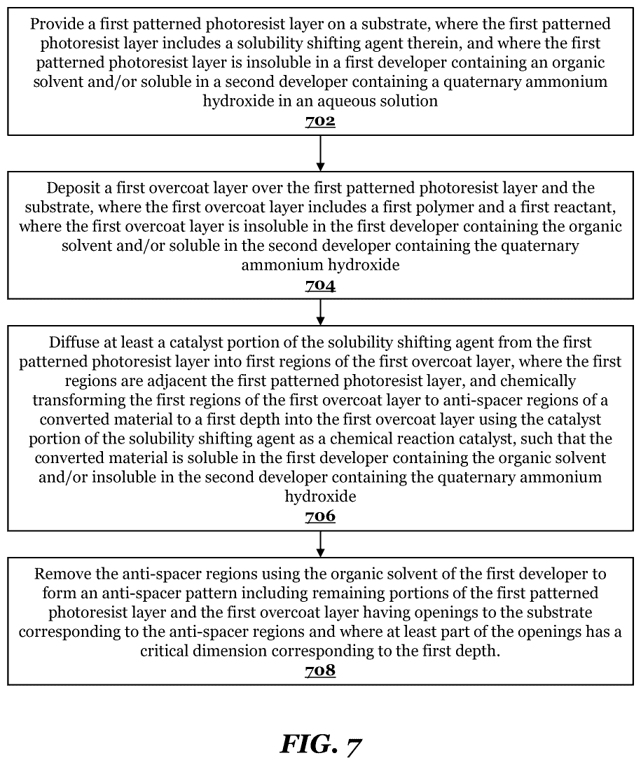

FIG. 7 is a flowchart illustrating a method for forming an anti-spacer patterned mask according to an embodiment of the present disclosure. In a method for forming a patterned mask, the method can include providing a first patterned photoresist layer on a substrate, where the first patterned photoresist layer includes a solubility shifting agent therein, and where the first patterned photoresist layer is insoluble in a first developer containing an organic solvent and/or soluble in a second developer containing a quaternary ammonium hydroxide in an aqueous solution (box 702).

In a method for forming an anti-spacer patterned mask, the method can include depositing a first overcoat layer over the first patterned photoresist layer and the substrate, where the first overcoat layer includes a first polymer and a first reactant, where the first overcoat layer is insoluble in the first developer containing the organic solvent and/or soluble in the second developer containing the quaternary ammonium hydroxide (box 704).

In a method for forming an anti-spacer patterned mask, the method can include diffusing at least a catalyst portion of the solubility shifting agent from the first patterned photoresist layer into first regions of the first overcoat layer, where the first regions are adjacent the first patterned photoresist layer, and chemically transforming the first regions of the first overcoat layer to anti-spacer regions of a converted material to a first depth into the first overcoat layer using the catalyst portion of the solubility shifting agent as a chemical reaction catalyst, such that the converted material is soluble in the first developer containing the organic solvent and/or insoluble in the second developer containing the quaternary ammonium hydroxide (box 706).

In a method for forming an anti-spacer patterned mask, the method can include removing the anti-spacer regions using the organic solvent of the first developer to form an anti-spacer pattern including remaining portions of the first patterned photoresist layer and the first overcoat layer having openings to the substrate corresponding to the anti-spacer regions and where at least part of the openings has a critical dimension corresponding to the first depth (box 708).

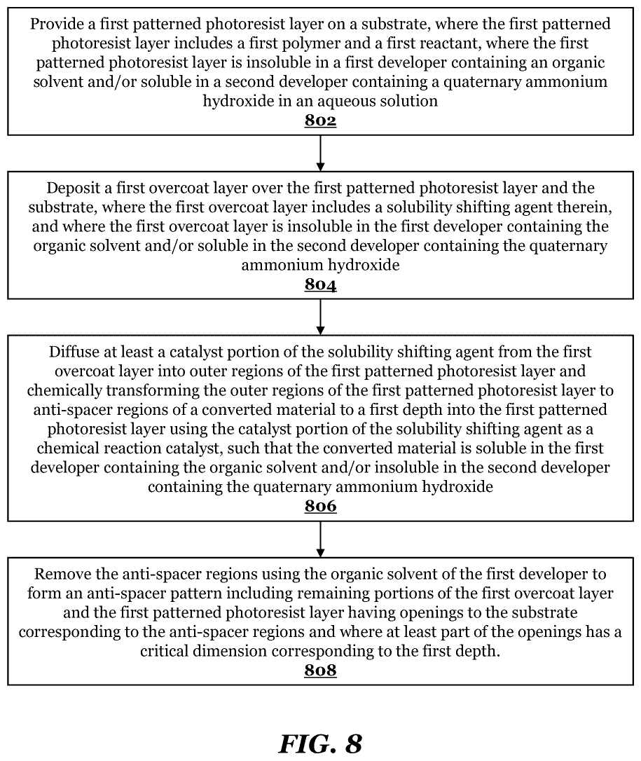

FIG. 8 is a flowchart illustrating a method for forming an anti-spacer patterned mask according to an embodiment of the present disclosure. In a method for forming a patterned mask, the method can include providing a first patterned photoresist layer on a substrate, where the first patterned photoresist layer includes a first polymer and a first reactant, where the first patterned photoresist layer is insoluble in a first developer containing an organic solvent and/or soluble in a second developer containing a quaternary ammonium hydroxide in an aqueous solution (box 802).

In a method for forming an anti-spacer patterned mask, the method can include depositing a first overcoat layer over the first patterned photoresist layer and the substrate, where the first overcoat layer includes a solubility shifting agent therein, and where the first overcoat layer is insoluble in the first developer containing the organic solvent and/or soluble in the second developer containing the quaternary ammonium hydroxide (box 804).

In a method for forming an anti-spacer patterned mask, the method can include diffusing at least a catalyst portion of the solubility shifting agent from the first overcoat layer into outer regions of the first patterned photoresist layer and chemically transforming the outer regions of the first patterned photoresist layer to anti-spacer regions of a converted material to a first depth into the first patterned photoresist layer using the catalyst portion of the solubility shifting agent as a chemical reaction catalyst, such that the converted material is soluble in the first developer containing the organic solvent and/or insoluble in the second developer containing the quaternary ammonium hydroxide (box 806).

In a method for forming an anti-spacer patterned mask, the method can include removing the anti-spacer regions using the organic solvent of the first developer to form an anti-spacer pattern including remaining portions of the first overcoat layer and the first patterned photoresist layer having openings to the substrate corresponding to the anti-spacer regions and where at least part of the openings has a critical dimension corresponding to the first depth (box 808).

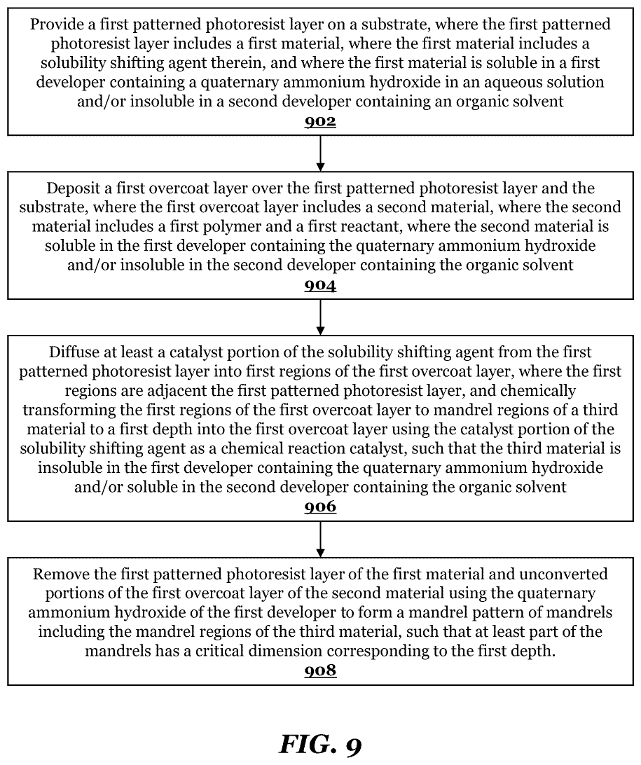

FIG. 9 is a flowchart illustrating a method for forming a patterned mask according to an embodiment of the present disclosure. In a method for forming a patterned mask, the method can include providing a first patterned photoresist layer on a substrate, where the first patterned photoresist layer includes a first material, where the first material includes a solubility shifting agent therein, and where the first material is soluble in a first developer containing a quaternary ammonium hydroxide in an aqueous solution and/or insoluble in a second developer containing an organic solvent (box 902).

In a method for forming a patterned mask, the method can include depositing a first overcoat layer over the first patterned photoresist layer and the substrate, where the first overcoat layer includes a second material, where the second material includes a first polymer and a first reactant, where the second material is soluble in the first developer containing the quaternary ammonium hydroxide and/or insoluble in the second developer containing the organic solvent (box 904).

In a method for forming a patterned mask, the method can include diffusing at least a catalyst portion of the solubility shifting agent from the first patterned photoresist layer into first regions of the first overcoat layer, where the first regions are adjacent the first patterned photoresist layer, and chemically transforming the first regions of the first overcoat layer to mandrel regions of a third material to a first depth into the first overcoat layer using the catalyst portion of the solubility shifting agent as a chemical reaction catalyst, such that the third material is insoluble in the first developer containing the quaternary ammonium hydroxide and/or soluble in the second developer containing the organic solvent (box 906).

In a method for forming a patterned mask, the method can include removing the first patterned photoresist layer of the first material and unconverted portions of the first overcoat layer of the second material using the quaternary ammonium hydroxide of the first developer to form a mandrel pattern of mandrels including the mandrel regions of the third material, such that at least part of the mandrels has a critical dimension corresponding to the first depth (box 908).

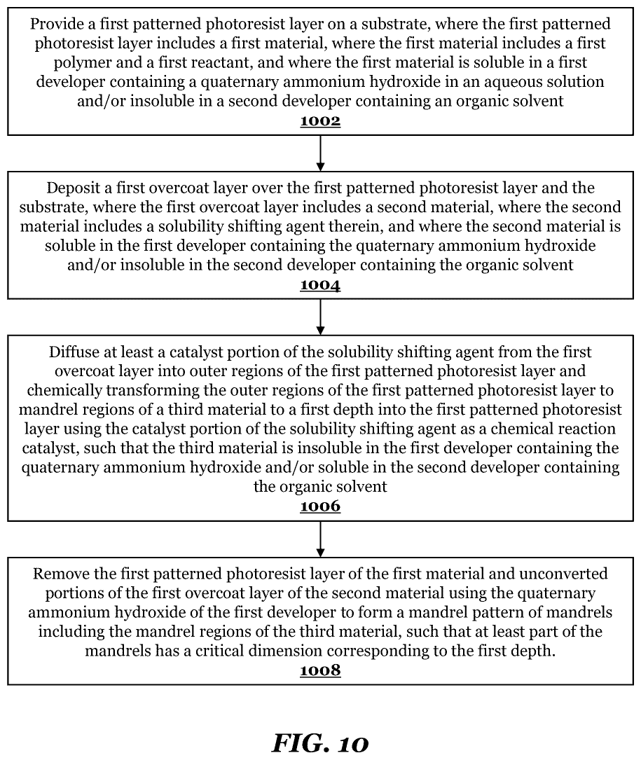

FIG. 10 is a flowchart illustrating a method for forming a patterned mask according to an embodiment of the present disclosure. In a method for forming a patterned mask, the method can include providing a first patterned photoresist layer on a substrate, where the first patterned photoresist layer includes a first material, where the first material includes a first polymer and a first reactant, and where the first material is soluble in a first developer containing a quaternary ammonium hydroxide in an aqueous solution and/or insoluble in a second developer containing an organic solvent (box 1002).

In a method for forming a patterned mask, the method can include depositing a first overcoat layer over the first patterned photoresist layer and the substrate, where the first overcoat layer includes a second material, where the second material includes a solubility shifting agent therein, and where the second material is soluble in the first developer containing the quaternary ammonium hydroxide and/or insoluble in the second developer containing the organic solvent (box 1004).

In a method for forming a patterned mask, the method can include diffusing at least a catalyst portion of the solubility shifting agent from the first overcoat layer into outer regions of the first patterned photoresist layer and chemically transforming the outer regions of the first patterned photoresist layer to mandrel regions of a third material to a first depth into the first patterned photoresist layer using the catalyst portion of the solubility shifting agent as a chemical reaction catalyst, such that the third material is insoluble in the first developer containing the quaternary ammonium hydroxide and/or soluble in the second developer containing the organic solvent (box 1006).

In a method for forming a patterned mask, the method can include removing the first patterned photoresist layer of the first material and unconverted portions of the first overcoat layer of the second material using the quaternary ammonium hydroxide of the first developer to form a mandrel pattern of mandrels including the mandrel regions of the third material, such that at least part of the mandrels has a critical dimension corresponding to the first depth (box 1008).

Next, many example materials for a first intermediate structure 11, a second intermediate structure 21, a first material, a second material, an SSA 15, a first polymer 41, a first reactant 51, a third material or a converted material of a converted region 53, an overcoat 106, a developer containing an organic solvent, and a developer containing a quaternary ammonium hydroxide in an aqueous solution, relating to the example embodiments of FIGS. 1A to 10, and that can be implemented in other embodiments of the present disclosure, will be described.

In an example embodiment of the present disclosure, a first polymer 41, a first reactant 51, and a resulting converted material of the converted region 53 (or 111) that is soluble in a developer containing an organic solvent can be as follows:

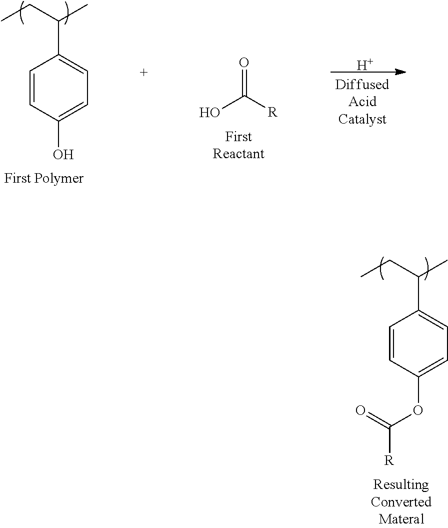

In an example embodiment of the present disclosure, a first polymer 41, a first reactant 51, and a resulting converted material of the converted region 53 (or 111) that is soluble in a developer containing an organic solvent can be as follows:

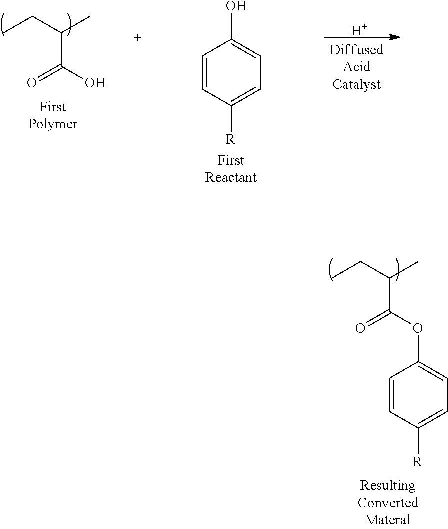

Conventional chemically-amplified resists (CAR) can include polymers with protected alcohol/phenol or carboxylic acid groups. When exposed to a strong acid, the protecting group can be cleaved to give a free alcohol/phenol or carboxylic acid that can change solubility of the polymer. A relief pattern can be formed by layering photoresist onto a substrate and developing the photoresist. The photoresist can be developed according to any suitable procedure, such as exposure to actinic radiation followed by rinsing with a photoresist developer. To impart a shape or relief pattern in the developed resist, a mask can be used to block portions of the photoresist from the actinic radiation. After the actinic radiation is applied, the unexposed portions of the photoresist can have a different solubility than the exposed portion of the photoresist. The exposed photoresist layer can be then developed with a suitable developer to selectively remove those regions of the photoresist layer that are soluble in the developer while the remaining insoluble regions form the resulting photoresist pattern relief image or patterned photoresist layer.

In the case of a conventional positive-tone development (PTD) process, the exposed portions of the photoresist become soluble in an aqueous base developer, such as a developer containing the quaternary ammonium hydroxide, or more particularly such as commonly-used Tetramethylammonium hydroxide (TMAH), while the unexposed regions can remain insoluble in the developer containing the quaternary ammonium hydroxide. Conversely, in a negative-tone development (NTD) process, the unexposed portions of the photoresist can be soluble in an organic solvent developer, while the exposed regions remain insoluble in the organic solvent developer, such as n-butyl acetate or 2-heptanone.

There can be disadvantages of using these conventional patterning approaches with conventional CAR resists. PTD processes using aqueous TMAH developer can be prone to pattern collapse as a result of the high surface tension of the aqueous developer. NTD processes can improve this performance as the surface tension of the organic solvent developer is generally lower than that of an aqueous base developer, such as TMAH. Therefore, NTD processes can be preferred for forming small features. However, the area of the photoresist film that needs to be exposed, and the resulting exposure dose, can be dramatically different for PTD and NTD processes using conventional processes. For example, in the case of patterning isolated trenches where only a small portion of the photoresist film will be removed by the developer, it can be advantageous to use a conventional PTD process to remove these sparse exposed areas to minimize exposure dose. To use a conventional NTD process, the majority of the photoresist film would need to be exposed, thereby leading to significantly higher exposure dose, which consumes more electricity for the fabrication processes (which is generally not desired).

To alleviate this challenge, it would be desirable to have a PTD process wherein the developer was an organic solvent instead of aqueous TMAH. The inventors have discovered new photoresist compositions and patterning processes that enable organic solvent developers to be used with PTD processes such that the exposed portion of the resist film is removed by the organic solvent developer.

For describing some example materials that can be implemented and used in an embodiment of the present disclosure, some example definitions will be provided next. These definitions are intended to supplement and illustrate, not preclude, definitions known to those of skill in the art, as can be apparent to one of ordinary skill in the art to which the present disclosure pertains.

The term “independently selected” as used herein can indicate that the R groups, such as, R1, R2, R3, R4, and R5 can be identical or different (e.g., R1, R2, R3, R4, and R5 may all be substituted alkyls or R1 and R2 may be a substituted alkyl and R3 may be an aryl, etc.). Use of the singular can include use of the plural, and vice versa (e.g., a hexane solvent can include hexanes). A named R group can generally have the structure that is recognized in the art as corresponding to R groups having that name.

The term “aliphatic” can refer to a non-aromatic saturated or unsaturated straight or branched hydrocarbon radical of from 1 to 40 carbon atoms or from 1 to 18 carbon atoms.

By “substituted” as in “substituted aliphatic moiety,” “substituted aryl,” “substituted alkyl,” and “substituted alkenyl,” as alluded to in some of the aforementioned definitions, can be indicate that in the hydrocarbyl, hydrocarbylene, alkyl, alkenyl, aryl or other moiety, at least one hydrogen atom bound to a carbon atom is replaced with one or more substituents that are groups such as hydroxyl, alkoxy, alkylthio, amino, halo, and silyl, to name a few. When the term “substituted” appears prior to a list of possible substituted groups, it can be intended that the term applies to every member of that group. For example, the phrase “substituted alkyl, alkenyl, and alkynyl” can be interpreted as “substituted alkyl, substituted alkenyl, and substituted alkynyl.” Similarly, “optionally substituted alkyl, alkenyl, and alkynyl” can be interpreted as “optionally substituted alkyl, optionally substituted alkenyl, and optionally substituted alkynyl.”

The term “substitution” can indicate each hydrogen atom (H) bonded to a carbon atom or heteroatom of a corresponding unsubstituted compound or functional group is replaced by a substituent (e.g., Rs). The term “polysubstitution” can indicate each of at least two, but not all, hydrogen atoms bonded to carbon atoms or heteroatoms of a corresponding unsubstituted compound or functional group is replaced by a substituent. The (C1-C18)alkylene and (C1-C8)alkylene substituents can be especially useful for forming substituted chemical groups that are bicyclic or tricyclic analogs of corresponding monocyclic or bicyclic unsubstituted chemical groups, for example.

The term “(C1-C40)hydrocarbyl” can refer to a hydrocarbon radical of from 1 to 40 carbon atoms and the term “(C1-C40)hydrocarbylene” can refer to a hydrocarbon diradical of from 1 to 40 carbon atoms, in which each hydrocarbon radical and diradical independently is aromatic (6 carbon atoms or more) or non-aromatic, saturated or unsaturated, straight chain or branched chain, cyclic (including mono- and poly-cyclic, fused and non-fused polycyclic, including bicyclic; 3 carbon atoms or more) or acyclic, or a combination of two or more thereof, and each hydrocarbon radical and diradical independently can be the same as or different from another hydrocarbon radical and diradical, respectively, and independently can be unsubstituted or substituted by one or more Rs.

In the present disclosure, a (C1-C40)hydrocarbyl independently can be an unsubstituted or substituted (C1-C40)alkyl, (C3-C40)cycloalkyl, (C3-C20)cycloalkyl-(C1-C20)alkylene, (C6-C40)aryl, or (C6-C20)aryl-(C1-C20)alkylene. In some embodiments, each of the aforementioned (C1-C40)hydrocarbyl groups independently has a maximum of 20 carbon atoms (i.e., (C1-C20)hydrocarbyl) and in other embodiments, a maximum of 12 carbon atoms, for example.

The terms “(C1-C40)alkyl” and “(C1-C18)alkyl” can refer to a saturated straight or branched hydrocarbon radical of from 1 to 40 carbon atoms or from 1 to 18 carbon atoms, respectively, that is unsubstituted or substituted by one or more Rs. Examples of unsubstituted (C1-C40)alkyl are: unsubstituted (C1-C20)alkyl; unsubstituted (C1-C10)alkyl; unsubstituted (C1-C5)alkyl; methyl; ethyl; 1-propyl; 2-propyl; 1-butyl; 2-butyl; 2-methylpropyl; 1,1-dimethylethyl; 1-pentyl; 1-hexyl; 1-heptyl; 1-nonyl; and 1-decyl. Examples of substituted (C1-C40)alkyl are substituted (C1-C20) alkyl, substituted (C1-C10)alkyl, trifluoromethyl, and (C45)alkyl. The (C45)alkyl is, for example, a (C27-C40)alkyl substituted by one Rs, which is a (C1-C5)alkyl, respectively. In some embodiments, each (C1-C5)alkyl independently is methyl, trifluoromethyl, ethyl, 1-propyl, 1-methylethyl, or 1,1-dimethylethyl, for example.

The term “(C6-C40)aryl” can refer to an unsubstituted or substituted (by one or more Rs) mono-, bi-, or tricyclic aromatic hydrocarbon radical of from 6 to 40 carbon atoms, of which at least from 6 to 14 of the carbon atoms are aromatic ring carbon atoms, and the mono-, bi-, or tricyclic radical comprises 1, 2 or 3 rings, respectively, wherein the 1 ring is aromatic and the 2 or 3 rings independently are fused or non-fused and at least one of the 2 or 3 rings is aromatic. Examples of unsubstituted (C6-C40)aryl are: unsubstituted (C6-C20)aryl unsubstituted (C6-C18)aryl; 2-(C1-C5)alkyl-phenyl; 2,4-bis(C1-C5)alkyl-phenyl; phenyl; fluorenyl; tetrahydrofluorenyl; indacenyl; hexahydroindacenyl; indenyl; dihydroindenyl; naphthyl; tetrahydronaphthyl; and phenanthrene. Examples of substituted (C6-C40)aryl are: substituted (C1-C20)aryl; substituted (C6-C18)aryl; 2,4-bis[(C20)alkyl]-phenyl; polyfluorophenyl; pentafluorophenyl; and fluoren-9-one-1-yl.

The term “(C3-C40)cycloalkyl” can refer to a saturated cyclic hydrocarbon radical of from 3 to 40 carbon atoms that is unsubstituted or substituted by one or more Rs. Other cycloalkyl groups (e.g., (C3-C12)alkyl) can be defined in an analogous manner. Examples of unsubstituted (C3-C40)cycloalkyl are: unsubstituted (C3-C20)cycloalkyl, unsubstituted (C3-C10)cycloalkyl, cyclopropyl, cyclobutyl, cyclopentyl, cyclohexyl, cycloheptyl, cyclooctyl, cyclononyl, and cyclodecyl. Examples of substituted (C3-C40)cycloalkyl are: substituted (C3-C20)cycloalkyl, substituted (C3-C10)cycloalkyl, cyclopentanon-2-yl, and 1-fluorocyclohexyl.

Examples of (C1-C40)hydrocarbylene are: unsubstituted or substituted (C6-C40)arylene, (C3-C40)cycloalkylene, and (C1-C40)alkylene (e.g., (C1-C20)alkylene). In some embodiments, the diradicals are a same carbon atom (e.g., —CH2-) or on adjacent carbon atoms (i.e., 1,2-diradicals), or are spaced apart by one, two, or more intervening carbon atoms (e.g., respective 1,3-diradicals, 1,4-diradicals, etc.), for example. Some embodiments incorporate a 1,2-, 1,3-, 1,4-, or an alpha, omega-diradical, and others a 1,2-diradical, for example. The alpha, omega-diradical can be a diradical that has maximum carbon backbone spacing between the radical carbons. Some embodiments can incorporate a 1,2-diradical, 1,3-diradical, or 1,4-diradical version of (C6-C18)arylene, (C3-C20)cycloalkylene, or (C2-C20)alkylene.

The term “(C1-C40)alkylene” can refer to a saturated straight chain or branched chain diradicals (i.e., the radicals are not on ring atoms) of from 1 to 40 carbon atoms that is unsubstituted or substituted by one or more Rs. Examples of unsubstituted (C1-C40)alkylene are: unsubstituted (C1-C20)alkylene, including unsubstituted 1,2-(C2-C10)alkylene; including unsubstituted 1,3-(C3-C10)alkylene; 1,4-(C4-C10)alkylene; —C—, —CH2CH2-, —(CH2)-, —CH2CHCH3, —(CH2)4-, —(CH2)5-, —(CH2)6-, —(CH2)7-, —(CH2)8-, and —(CH2)4C(H)(CH3)-. Examples of substituted (C1-C40)alkylene are: substituted (C1-C20)alkylene, —CF2-, —C(O)—, and —(CH2)14C(CH3)2(CH2)5- (i.e., a 6,6-dimethyl substituted normal-1,20-eicosylene). As mentioned previously two Rs may be taken together to form a (C1-C18)alkylene, examples of substituted (C1-C40)alkylene also include 1,2-bis(methylene)cyclopentane, 1,2-bis(methylene)cyclohexane, 2,3-bis(methylene)-7,7-dimethyl-bicyclo[2.2.1]heptane, and 7,3-bis(methylene)bicyclo[2.2.2]octane.

The term “(C3-C40)cycloalkylene” can refer to a cyclic diradical (i.e., the radicals are on ring atoms) of from 3 to 40 carbon atoms that is unsubstituted or substituted by one or more Rs.

The term “heteroatom,” “heterohydrocarbon” can refer to a molecule or molecular framework in which one or more carbon atoms are replaced with an atom other than carbon or hydrogen. The term “(C1-C40)heterohydrocarbyl” can refer to a heterohydrocarbon radical of from 1 to 40 carbon atoms and the term “(C1-C40)heterohydrocarbylene” can refer to a heterohydrocarbon diradical of from 1 to 40 carbon atoms, and each heterohydrocarbon independently has one or more heteroatoms, for example O, S, S(O), S(O)2, Si(RC)2, P(RP), and N(RN). Independently each RC is unsubstituted (C1-C18)hydrocarbyl, each RP is unsubstituted (C1-C19)hydrocarbyl, and each RN is unsubstituted (C1-C18)hydrocarbyl or absent. When RN is absent then N comprises —N═. The heterohydrocarbon radical, and each of the heterohydrocarbon diradicals, independently is on a carbon atom or heteroatom thereof, and in most embodiments, it is on a carbon atom when bonded to a heteroatom formula (I) or to a heteroatom of another heterohydrocarbyl or heterohydrocarbylene. Each (C1-C40)heterohydrocarbyl and (C1-C40)heterohydrocarbylene independently is unsubstituted or substituted (by one or more Rs), aromatic or non-aromatic, saturated or unsaturated, straight chain or branched chain, cyclic (including mono- and poly-cyclic, fused and non-fused polycyclic) or acyclic, or a combination of two or more thereof; and each is respectively the same as or different from another.

In some embodiments, the (C1-C40)heterohydrocarbyl independently can be unsubstituted or substituted (C1-C40)heteroalkyl, (C1-C40)hydrocarbyl-O—, (C1-C40)hydrocarbyl-S—, (C1-C40)hydrocarbyl-S(O)—, (C1-C40)hydrocarbyl-S(O)₂—, (C1-C40)hydrocarbyl-Si(RC)2-, (C1-C40)hydrocarbyl-N(RN)—, (C1-C40)hydrocarbyl-P(RP)—, (C2-C40)heterocycloalkyl, (C2-C19)heterocycloalkyl-(C1-C20)alkylene, (C3-C20cycloalkyl-(C1-C19)heteroalkylene, (C2-C19)heterocycloalkyl-(C1-C20)heteroalkylene, (C1-C40)heteroaryl, (C1-C19)heteroaryl-(C1-C20)alkylene, (C6-C20)aryl-(C1-C19)heteroalkylene, or (C1-C19)heteroaryl-(C1-C20)heteroalkylene, for example.

The term “(C4-C40)heteroaryl” can refer to an unsubstituted or substituted (by one or more Rs) mono-, bi-, or tricyclic heteroaromatic hydrocarbon radical of from 1 to 40 total carbon atoms and from 1 to 4 heteroatoms, and the mono-, bi-, or tricyclic radical can include 1, 2, or 3 rings, respectively, wherein the 2 or 3 rings independently can be fused or non-fused and at least one of the 2 or 3 rings can be heteroaromatic. Other heteroaryl groups (e.g., (C4-C12)heteroaryl) can be defined in an analogous manner. The monocyclic heteroaromatic hydrocarbon radical can be a 5-membered or 6-membered ring. The 5-membered ring can have from 2 to 4 carbon atoms and from 3 to 1 heteroatoms, respectively, each heteroatom being 0, S, N, or P. Examples of 5-membered ring heteroaromatic hydrocarbon radical are: pyrrol-1-yl; pyrrol-2-yl; furan-3-yl; thiophen-2-yl; pyrazol-1-yl; isoxazol-2-yl; isothiazol-5-yl; imidazol-2-yl; oxazol-4-yl; thiazol-2-yl; 1,2,4-triazol-1-yl; 1,3,4-oxadiazol-2-yl; 1,3,4-thiadiazol-2-yl; tetrazol-1-yl; tetrazol-2-yl; and tetrazol-5-yl. The 6-membered ring can have 4 or 5 carbon atoms and 2 or 1 heteroatoms, the heteroatoms being N or P. Examples of 6-membered ring heteroaromatic hydrocarbon radical are: pyridine-2-yl; pyrimidin-2-yl; and pyrazin-2-yl. The bicyclic heteroaromatic hydrocarbon radical can be a fused 5,6- or 6,6-ring system. Examples of the fused 5,6-ring system bicyclic heteroaromatic hydrocarbon radical are: indol-1-yl; and benzimidazole-1-yl. Examples of the fused 6,6-ring system bicyclic heteroaromatic hydrocarbon radical are: quinolin-2-yl; and isoquinolin-1-yl. The tricyclic heteroaromatic hydrocarbon radical can be a fused 5,6,5-; 5,6,6-; 6,5,6-; or 6,6,6-ring system. An example of the fused 5,6,5-ring system is 1,7-dihydropyrrolo[3,2-f]indol-1-yl. An example of the fused 5,6,6-ring system is 1H-benzo[f]indol-1-yl. An example of the fused 6,5,6-ring system is 9H-carbazol-9-yl. An example of the fused 6,5,6-ring system is 9H-carbazol-9-yl. An example of the fused 6,6,6-ring system is acrydin-9-yl.

The aforementioned heteroalkyl and heteroalkylene groups can be saturated straight or branched chain radicals or diradicals, respectively, containing (C1-C40) carbon atoms, or fewer carbon atoms and one or more of the heteroatoms Si(Rc)2, P(RP), N(RN), N, O, S, S(O), and S(O)2 as defined above, wherein each of the heteroalkyl and heteroalkylene groups independently can be unsubstituted or substituted by one or more Rs.

Examples of unsubstituted (C2-C40)heterocycloalkyl are: unsubstituted (C2-C20)heterocycloalkyl, unsubstituted (C2-C10)heterocycloalkyl, aziridin-1-yl, oxetan-2-yl, tetrahydrofuran-3-yl, pyrrolidin-1-yl, tetrahydrothiophen-S,S-dioxide-2-yl, morpholin-4-yl, 1,4-dioxan-2-yl, hexahydroazepin-4-yl, 3-oxa-cycloodyl, 5-thio-cyclononyl, and 2-aza-cyclodecyl.

The term “halogen atom” can refer to fluorine atom (F), chlorine atom (Cl), bromine atom (Br), or iodine atom (I) radical. The terms “halide” can refer to fluoride (F—), chloride (Cl—), bromide (Br—), or iodide (I—) anion.

The term “saturated” can refer to lacking carbon-carbon double bonds, carbon-carbon triple bonds, and (in heteroatom-containing groups) carbon-nitrogen, carbon-phosphorous, and carbon-silicon double bonds. Where a saturated chemical group is substituted by one or more substituents Rs, one or more double and/or triple bonds optionally may or may not be present in substituents Rs. The term “unsaturated” can refer to containing one or more carbon-carbon double bonds, carbon-carbon bonds, and (in heteroatom-containing groups) carbon-nitrogen, carbon-phosphorous, and carbon-silicon double bonds, not including any such double bonds that may be present in substituents Rs, if any, or in (hetero) aromatic rings, if any.

### Conventional Chemically-Amplified Resist (CAR)

In an embodiment of present disclosure, a composition of a first intermediate structure 11 can be made starting with a conventional chemically amplified resist composition, commonly referred to as a CAR, that can include a CAR polymer, a photoacid generator (as an SSA 15), a solvent (e.g., for use in the spin-on deposition, which can be evaporated during the deposition), and may also contain additional optional components.

For example, in an embodiment of the present disclosure, the first intermediate structure 11 of FIG. 1A can be made starting with a chemically amplified resist composition that can include a CAR polymer, a photoacid generator (as an SSA 15), a solvent, and may also contain additional optional components. For example, in an embodiment of the present disclosure, the first patterned photoresist layer 101 of FIG. 2A can be made starting with a chemically amplified resist composition that can include a CAR polymer, a photoacid generator (as an SSA 15), a solvent, and may also contain additional optional components.

### CAR Polymer

In an embodiment of the present disclosure in which a CAR polymer is used for forming a first intermediate structure 11, the CAR polymer may be any standard polymer typically used in photoresist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting groups may alter the reactivity and solubility of the polymer included in the first photoresist. As will be appreciated by one having ordinary skill in the art, various protecting groups may be used for this reason. Acid-labile groups can include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups can be also commonly referred to in the art as “acid-decomposable groups”, “acid-cleavable groups,” “acid-cleavable protecting groups,” “acid-labile protecting groups,” “acid-leaving groups,” and “acid-sensitive groups.” The acid-labile group may, on decomposition, form a carboxylic acid, alcohol group, or fluoroalcohol group on the polymer.

### Photoacid Generator (PAG)

In an embodiment of the present disclosure in which a photoacid generator (PAG) is used for forming a first intermediate structure 11 with an SSA 15 therein (e.g., in some embodiments, the conventional CAR composition can include a PAG) (e.g., the PAG is a compound capable of generating an acid upon irradiation with actinic rays or radiation), the PAG may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and capable of generating an acid upon irradiation with actinic rays or radiation, and a mixture thereof can be used. Examples of the PAG can include a diazonium salt, a phosphonium salt, a sulfonium salt, an iodonium salt, imidosulfonate, oxime sulfonate, diazodisulfone, disulfone, and o-nitrobenzyl sulfonate.

Suitable classes of PAGs generating sulfonic acids can include, but are not limited to, sulfonium or iodonium salts, oximidosulfonates, bissulfonyldiazomethanes, and nitrobenzylsulfonate esters, for example. The PAG can be in non-polymerized or polymeric form, for example, present in a polymerized repeating unit of the polymer matrix. Suitable photoacid generator compounds are disclosed, for example, in U.S. Pat. Nos. 5,558,978, 5,468,589, 6,844,132, 6,855,476, and 6,911,297, which are incorporated herein by reference in their entireties. In some embodiments, a preferred PAGs can include one or more of tris(perfluoroalkylsulfonyl)methides, tris(perfluoroalkylsulfonyl)imides, and those generating perfluoroalkylsulfonic acids, for example.

Additional examples of suitable PAGs can include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts can include, but are not limited to, diphenyl iodonium perfluorobutanesulfonate, bis-(t-butylphenyl)iodonium perfluorobutanesulfonate, bis-(t-butylphenyl)iodonium, perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate.

Examples of tris(perfluoroalkylsulfonyl)methide and tris(perfluoroalkylsulfonyl)imide PAGs can be found in U.S. Pat. Nos. 5,554,664 and 6,306,555, each of which is incorporated herein in its entirety. For an SSA 15 of an embodiment, additional examples of PAGs of this type can be found in Proceedings of SPIE, Vol. 4690, pp. 817-828 (2002).

Suitable methide and imide PAGs can include, but are not limited to, triphenylsulfonium tris(trifluoromethylsulfonyl)methide, methylphenyldiphenylsulfonium tris(perfluoroethylsulfonyl)methide, triphenylsulfonium tris(perfluorobutylsulfonyl)methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

Further examples of suitable photoacid generators can be bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-icyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, and 2,4-dinitrobenzyl p-trifluoromethylbenzenesulfonate.

Some more preferred PAGs can be triarylsulfonium perfluoroalkylsulfonates and triarylsulfonium tris(perfluoroalkylsulfonyl)methides. Some more preferred PAGs can include triphenylsulfonium perfluorooctanesulfonate (TPS-PFOS), triphenylsulfonium perfluorobutanesulfonate (TPS-Nonaflate), methyiphenyldiphenylsulfonium perfluorooctanesulfonate (TDPS-PFOS), tris(-t-butylphenyl)sulfonium perfluorobutanesulfonate CTBPS-Nonaflate), triphenylsulfonium tris(trifluoromethylsulfonyl)methide (TPS-C1), or methylphenyldiphenylsulfonium tris(perfluoroethylsulfonyl)methide.

Additional PAG compounds can include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; di-t-butyphenyliodonium perfluorobutanesulfonate, or di-t-butyphenyliodonium camphorsulfonate.

Non-ionic sulfonates and sulfonyl compounds can function as photoacid generators, for example: nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; or halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine.

Suitable non-polymerized photoacid generators that can be used are further described in U.S. Pat. No. 8,431,325 to Hashimoto et al. in column 37, lines 11-47 and columns 41-91. Other suitable sulfonate PAGs can include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically can include an anion having a sulfonate group or a non-sulfonate type group, such as a sulfonamidate group, a sulfonimidate group, a methide group, or a borate group.

In an embodiment, a photoresist composition may optionally include a plurality of PAGs. The plural PAGs can be polymeric, non-polymeric, or can include both polymeric and non-polymeric PAGs. In some embodiments, each of the plurality of PAGs can be non-polymeric. In some embodiments, when a plurality of PAGs are used, a first PAG can include a sulfonate group on the anion and a second PAG can include an anion that is free of sulfonate groups, such anion containing for example, a sulfonamidate group, a sulfonimidate group, a methide group, or a borate group, such as described above, for example.

In some embodiments, the PAG can be a polymeric PAG, wherein the compound capable of generating an acid upon irradiation with actinic rays or radiation is introduced into the main or side chain of the polymer. Examples can include, for example, PAG compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853, and JP-A-63-146029.

In some embodiments, a photoresist composition can include a non-polymerized photoacid generator in an amount from about 1 to 65 wt %, from about 5 to 55 wt %, or from about 8 to 30 wt %, based on total solids of the photoresist composition, for example. In some embodiments, a photoresist composition can include two or more different non-polymerized photoacid generators in a combined amount from about 1 to 65 wt %, from about 5 to 55 wt %, or from about 8 to 30 wt %, based on total solids of the photoresist composition, for example. In some embodiments, a photoacid generator mixture can include two or three photoacid generators. Such mixtures can be of a same class or different classes. Examples of some preferred mixtures can include sulfonium salts with bis-sulfonyldiazomethane compounds, sulfonium salts and imidosulfonates, and two sulfonium salts, for example.

### Solvent

Before deposition and/or at the time of deposition, a conventional chemically amplified resist composition in an embodiment of the present disclosure can further include a solvent for dissolving the components of the composition and facilitating its coating on a substrate, and most of or all of the solvent can be evaporated during the deposition operation, for example. In an embodiment of the present disclosure in which a solvent is used for forming a first intermediate structure 11, preferably, the solvent can be an organic solvent conventionally used in the manufacture of electronic devices. Suitable solvents can include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol and 4-methyl-2-pentanol; propylene glycol monomethyl ether (PGME), ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; water, or any combination thereof. Of these, preferred solvents can be PGME, PGMEA, EL, GBL, HBM, CHO, or any combination thereof. The total solvent content (i.e., cumulative solvent content for all solvents) in the photoresist compositions is typically from 40 to 99 wt %, more typically from 70 to 99 wt %, and still more typically from 85 to 99 wt %, based on total weight of the photoresist composition, for example. The desired solvent content can depend, for example, on the desired thickness of the coated photoresist layer and coating conditions.

### Optional Additives

Before deposition and/or at the time of deposition, a conventional chemically amplified resist composition in an embodiment of the present disclosure can further include one or more additional optional additives (which can be sometimes referred to as a quencher as an example). In an embodiment of the present disclosure in which a solvent is used for forming a first intermediate structure 11, optional additives can include actinic and contrast dyes, anti-striation agents, plasticizers, speed enhancers, sensitizers, photo-decomposable quenchers (also known as photo-decomposable bases), basic quenchers, surfactants, and the like, or any combination thereof. If present, the optional additives are typically present in the photoresist compositions in an amount from 0.01 to 10 wt %, based on total solids of the photoresist composition, for example.

Photo-decomposable quenchers can generate a weak acid upon irradiation. The acid generated from a photo-decomposable quencher can be not strong enough to react rapidly with acid-labile groups that are present in the resist matrix. Example photo-decomposable quenchers can include, for example, photo-decomposable cations, and preferably those also useful for preparing strong acid generator compounds, paired with an anion of a weak acid (pKa>−1) such as, for example, an anion of a C1-20 carboxylic acid or C1-20 sulfonic acid. Example carboxylic acids can include formic acid, acetic acid, propionic acid, tartaric acid, succinic acid, cyclohexanecarboxylic acid, benzoic acid, salicylic acid, and the like. Example sulfonic acids can include p-toluene sulfonic acid, camphor sulfonic acid and the like. In a preferred embodiment, the photo-decomposable quencher can be a photo-decomposable organic zwitterion compound such as diphenyliodonium-2-carboxylate.

The photo-decomposable quencher can be in non-polymeric or polymer-bound form. When in polymeric form, the photo-decomposable quencher can be present in polymerized units on the first polymer or second polymer. The polymerized units containing the photo-decomposable quencher are typically present in an amount from 0.1 to 30 mole %, preferably from 1 to 10 mole %, and more preferably from 1 to 2 mole %, based on total repeating units of the polymer, for example.

Example basic quenchers can include, for example: linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N1,N1,N3,N3-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; and optionally substituted pyrrolidones such as 2-pyrrolidone and cyclohexyl pyrrolidine.

The basic quenchers can be in non-polymeric or polymer-bound form. When in polymeric form, the quencher can be present in polymerized units on the polymer. The polymerized units containing the quencher are typically present in an amount of from 0.1 to 30 mole %, preferably from 1 to 10 mole %, and more preferably from 1 to 2 mole %, based on total repeating units of the polymer, for example.

Example surfactants can include fluorinated and non-fluorinated surfactants and can be ionic or non-ionic, with non-ionic surfactants being preferable. Example fluorinated non-ionic surfactants can include: perfluoro C4 surfactants, such as FC-4430 and FC-4432 surfactants, available from 3M Corporation; and fluorodiols such as POLYFOX PF-636, PF-6320, PF-656, and PF-6520 fluorosurfactants from Omnova. In an embodiment, the photoresist composition can further include a surfactant polymer including a fluorine-containing repeating unit.

### Inventive Photoresist Composition

In an embodiment of present disclosure, a second intermediate structure 21 can be made starting with an inventive photoresist chemical composition, which can be a chemically amplified photosensitive composition that can include a first polymer 41, a first reactant 51 (e.g., a reactive species), a photoacid generator (PAG), a solvent, and may also contain additional optional components.

For example, in an embodiment of the present disclosure, the second intermediate structure 21 of FIG. 1A can be made starting with an inventive photoresist chemical composition 95 of FIG. 3F, which can be a chemically amplified photosensitive composition that can include a first polymer 41, a first reactant 51 (e.g., a reactive species), a photoacid generator (PAG) 96, a solvent 98, and may also contain additional optional components 99. For example, in an embodiment of the present disclosure, the first patterned photoresist layer 101 of FIG. 3A can be made starting with an inventive photoresist chemical composition 95 of FIG. 3F, which can be a chemically amplified photosensitive composition that can include a first polymer 41, a first reactant 51 (e.g., a reactive species), a photoacid generator (PAG) 96, a solvent 98, and may also contain additional optional components 99.

Furthermore or alternatively, such inventive photoresist composition 95 can be used more generally in as a photoresist material for forming any type of patterned photoresist layer using any suitable type of exposure process/operation. Using particular photoresist compositions of an embodiment of the present disclosure, such as the inventive photoresist chemical composition described here, can achieve notably improved lithographic performance, such as better contrast, higher resolution, and reduced roughness of resolved patterns.

Referring to FIGS. 3A and 3F, FIG. 3F is a cross-section view illustrating an inventive photoresist chemical composition 95 (as just described above) being deposited on a substrate 12. In an embodiment of the present disclosure, an inventive photoresist chemical composition 95 can include a first polymer 41, a first reactant 51, a PAG 96, a solvent 98, and an additional optional component 99 (e.g., quencher), in which additional optional component 99 can be omitted in some embodiments but is shown in FIG. 3F for illustration.

In FIG. 3F, the solvent 98 is illustrated as being evaporated (indicated by dashed arrows) during the deposition process, such as a spin-on deposition process. However, inventive photoresist chemical composition 95 can be deposited using any suitable deposition operation for forming a photoresist layer. The inventive photoresist chemical composition 95 can be patterned by selected exposure via a mask, which can activate the PAG 96 as a catalyst for a reaction between the first polymer 41 and the first reactant 51 in the selected exposed regions, thereby forming converted regions of a converted material, such that the converted material is soluble in a developer containing the organic solvent. Then, the converted regions of converted material can be developed and removed using the developer containing the organic solvent to form a patterned photoresist layer, such as the first patterned photoresist layer 101 of FIG. 3A, for example.

In an embodiment of the present disclosure, after depositing the inventive photoresist chemical composition 95 to form an unpatterned photoresist layer (preferably planar, ready for exposure and patterning using a mask), such unpatterned photoresist layer made using the inventive photoresist chemical composition 95 can still include the first polymer 41, the first reactant 51, and the PAG 96, and can be initially soluble in a developer containing a quaternary ammonium hydroxide and initially insoluble in a developer containing an organic solvent. And then after exposure via a mask pattern, the exposed portions/regions can be chemically converted using the PAG 96 (as an SSA) (e.g., using the acid generated from the PAG 96 by the radiation) as a catalyst to react the first polymer 41 and the first reactant 51 to form converted material, where the converted material becomes/is soluble in the developer containing an organic solvent and insoluble in the developer containing quaternary ammonium hydroxide. After such exposure, in some embodiments, the converted material can remain while the unconverted material is removed in a development to remove the unconverted material using the developer containing quaternary ammonium hydroxide, thus resulting in forming mandrels of the converted material for a patterned photoresist layer. Alternatively, after such exposure, in some embodiments, the converted material can be removed using the developer containing the organic solvent while the unconverted material remains, thus resulting in forming mandrels of unconverted material for a patterned photoresist layer (see, e.g., FIG. 3A).

Many example materials for the first polymer 41, the first reactant 51, the PAG 96, the solvent 98, and the additional optional component 99, of an inventive photoresist chemical composition 95, as well as many example materials of the converted material, the developer containing an organic solvent, and the developer containing quaternary ammonium hydroxide, relating to the example embodiment of FIG. 3F, have been described above and will be described below in the present disclosure. For example, at least some of the PAG options described above relating to the convention CAR photoresist can be included/used as a PAG 96 in an inventive photoresist chemical composition 95 of an embodiment of the present disclosure. For example, at least some of the solvent options described above relating to the convention CAR photoresist can be included/used a solvent 98 in an inventive photoresist chemical composition 95 of an embodiment of the present disclosure. For example, at least some of the optional additive materials (e.g., quenchers) described above relating to the convention CAR photoresist can be included/used as an optional additional component 99 in an inventive photoresist chemical composition 95 of an embodiment of the present disclosure. For example, at least some of the first polymer options described next can be included/used as a first polymer 41 in an inventive photoresist chemical composition 95 of an embodiment of the present disclosure. For example, at least some of the first reactant options described next can be included/used as a first reactant 51 in an inventive photoresist chemical composition 95 of an embodiment of the present disclosure.

In accordance with an embodiment of the present disclosure, a chemical composition for a photoresist material configured to be used in semiconductor manufacturing can include a chemically amplified photosensitive composition including a first polymer, a first reactant, a photoacid generator, and a solvent, wherein the chemically amplified photosensitive composition is configured such that after deposition and before exposure to radiation, the chemically amplified photosensitive composition is insoluble in a developer containing an organic solvent and is soluble in a developer containing a quaternary ammonium hydroxide in an aqueous solution. The chemical composition can further include an additional optional component, such as a quencher.

### First Polymer

Next, some example materials that can be implemented and used for a first polymer 41 referenced above while describing the example embodiments of FIGS. 1A to 10, and that can be implemented and used for a first polymer 41 in other embodiments of the present disclosure, will be described.

A first polymer 41 of an embodiment of the present disclosure can be a homopolymer or a copolymer having a plurality of distinct repeat units (also referred to as monomers), for example, two, three, four, or more distinct repeat units. A first polymer 41 can be composed of monomers including vinyl aromatic monomers such as styrene, acrylate, methacrylate, norbornene, or combinations thereof, or other monomers that can be polymerized into a polymer. The repeat units of a first polymer 41 can be all formed from (meth)acrylate monomers, can be all formed from (vinyl)aromatic monomers, or can be all formed from (meth) acrylate monomers and (vinyl) aromatic monomers, for example. A first polymer 41 can include one or more monomers that include reactive functional groups including alcohols or carboxylic acids. In some embodiments, the reactive functional group can include a hydroxy-aryl group. In some embodiments, a first polymer 41 can include para-hydroxystyrene. In some embodiments, a first polymer 41 can include a carboxylic acid functionality, such as acrylic acid or methacrylic acid. In some embodiments, a first polymer 41 can include an alcohol functionality, such as 2-hydroxyethyl acrylate or 2-hydroxyethyl methacrylate or an acrylate or methacrylate functionalized with a carbohydrate selected from a group of: allose, altrose, glucose, mannose, gulose, idose, galactose, talose, psicose, fructose, sorbose, tagatose; ribose, arabinose, xylose, lyxose, ribulose, xylulose, erythose, threose, erythrulose, glyceraldehydes, altro-heptulose, L-glycero-D-manno-heptose, or a derivative thereof, for example.

A first polymer 41 can have a repeating unit having an alicyclic hydrocarbon structure and/or an aromatic ring structure that does not have a reactive functional group. In some embodiments, a first polymer 41 can include one or more monomers of Formula 1:

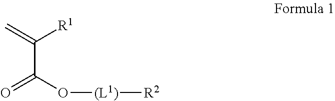

In Formula 1, R¹ can be hydrogen, fluorine, cyano, substituted or unsubstituted C₁₋₁₀ alkyl, or substituted or unsubstituted C₁₋₁₀ fluoroalkyl. In Formula 1, R¹ can be hydrogen, fluorine, or substituted or unsubstituted C₁₋₅ alkyl, typically methyl. In Formula 1, L¹ can be a single bond or a divalent linking group. For example, L¹ can be a single bond or a divalent linking group including one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₁₋₃₀ heterocycloalkylene, substituted or unsubstituted C₆₋₃₀ arylene, or substituted or unsubstituted C₄₋₃₀ heteroarylene, wherein L¹ optionally can further include one or more groups chosen, for example, from —O—, —C(O)—, —C(O)—O—, —S—, —S(O)₂—, and —N(R³)—S(O)₂—, wherein R³ can be hydrogen, substituted or unsubstituted C₁₋₂₀ alkyl, substituted or unsubstituted C₃₋₂₀ cycloalkyl, or substituted or unsubstituted C₁₋₂₀ heterocycloalkyl. In Formula 1, R² can be a monocyclic, polycyclic, or fused polycyclic C₄₋₂₀ lactone-containing group, or a monocyclic, polycyclic, or fused polycyclic C₄₋₂₀ sultone-containing group.

The total content of polymerized units comprising reactive functional groups is typically from 10 to 100 mole %, more typically from 10 to 90 mole % or from 30 to 70 mole %, based on total polymerized units of a first polymer 41 of an embodiment. In a first polymer 41 of an embodiment, the molar ratio of respective repeating structural units contained can be appropriately determined to control the dry etching resistance of photoresist, suitability for standard developer, adhesion to substrate, resist profile, and performances generally required of the photoresist, such as resolving power, heat resistance, and sensitivity, for example.

The form of a first polymer 41 in an embodiment of the present disclosure can be any form of a random type, a block type, a comb type, and a star type. When a first polymer 41 of an embodiment includes more than one type of repeat unit, it typically can take the form of a random copolymer. A first polymer 41 of an embodiment can be synthesized, for example, by polymerization of radicals, cations, or anions of an unsaturated monomer, corresponding to each structure. In an embodiment, it can be possible to obtain a target resin by using an unsaturated monomer corresponding to a precursor of each structure to perform polymerization, and then performing a polymer reaction.

A first polymer 41 in an embodiment of the present disclosure can be synthesized and purified by a suitable method (e.g., radical polymerization). Example synthesis and purification methods that can be suitable are described in paragraphs 0201 to 0202 of Japanese Patent Application Laid-Open No. 2008-292975, for example. The weight average molecular weight of a first polymer 41 in an embodiment of the present disclosure can be 7,000 or more as described above, such as in a range of 7,000 to 200,000, in a range of 7,000 to 50,000, in a range of 7,000 to 40,000, or in a range of 7,000 to 30,000, in terms of polystyrene by a Gel Permeation Chromatography (GPC) method, for example. If the weight average molecular weight is less than 7,000, the solubility in an organic developer can become higher, and thus, there can be a concern that a fine pattern can be not formed or not formed according to a given manufacturing specification.

Usually, the polydispersity (molecular weight distribution) of a first polymer 41 in an embodiment can be in a range of 1.0 to 3.0, in a range of 1.0 to 2.6, in a range of 1.0 to 2.0, or in a range of 1.4 to 2.0, for example. Generally, the smaller the molecular weight distribution is, the better the resolution and resist shape can be, and the smoother the side wall of the resist pattern can be, and thus roughness can be excellent in an embodiment of the present disclosure.

### First Reactant

Next, some example materials that can be implemented and used for a first reactant 51 referenced above while describing the example embodiments of FIGS. 1A to 10, and that can be implemented and used for a first reactant 51 in other embodiments of the present disclosure, will be described.

A first reactant 51 of an embodiment of the present disclosure can include a reactive species that can react with the reactive functional group of the polymer in presence of a strong acid. When a first polymer 41 of an embodiment includes an alcohol or hydroxy-(C₆-C₄₀)aryl group, such as from the monomer p-hydroxystyrene, a first reactant 51 can include a carboxylic acid, for example. For a first reactant 51 of an embodiment, a carboxylic acid can be of Formula 2:

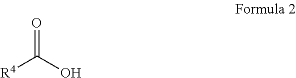

In Formula 2, R⁴ can be each independently linear (C₁-C₄₀)hydrocarbyl, branched (C₁-C₄₀)hydrocarbyl, monocyclic or polycyclic (C₃-C₄₀)hydrocarbyl, linear (C₂-C₄₀)hydrocarbenyl, branched (C₂-C₄₀)hydrocarbenyl, monocyclic or polycyclic (C₃-C₄₀)cyclohydrocarbenyl, monocyclic or polycyclic (C₆-C₄₀)aryl, or monocyclic or polycyclic (C₆-C₄₀) heteroaryl, each of which can be substituted or unsubstituted, and each R⁴ can be optionally including as part of its structure one or more groups chosen from —O—, —C(O)—, —C(O)O—, or —S—, for example.

For a first reactant 51 of an embodiment, a carboxylic acid reactive species can be selected from acetic acid, propionic acid, butyric acid, valeric acid, hexanoic acid, benzoic acid, lauric acid, stearic acid, oxalic acid, malonic acid, succinic acid, glutaric acid, adipic acid, citric acid, fumaric acid, lactic acid, pyruvic acid, tartaric acid, caprylic acid, or phthalic acid, heptanoic acid, octanoic acid, nonanoic acid, decanoic acid, 9-hydroxynonanoic acid, undecanoic acid, dodecanoic acid, tridecanoic acid, myristic acid, pentadecanoic acid, palmitic acid, heptadecanoic acid, nonadecanoic acid, arachidic acid, behenic acid, tricosanoic acid, lignoceric acid, hexacosanoic acid, octacosanoic acid, melissic acid, 5-Methylhexanoic acid, 6-Oxoheptanoic acid, 7-Oxooctanoic acid, 12-Methyltridecanoic acid, isosteric acid, isopalmitic acid, 6-methylhexanoic acid, 4-acetylbutyric acid, 4-methylhexanoic acid, 12-Methyltetradecanoic acid, 14-Methylhexadecanoic acid, 12-Hydroxyoctadecanoic acid, Neo-decanoic acid, 4-Methyloctanoic acid, Cyclohexanebutyric acid, 4-Methylnonanoic acid, Cyclohexanepentanoic acid, 4-Ethyloctanoic acid, 3-Cyclopentylpropionic acid, Cyclohexanepentanoic acid, mono-Methyl adipate, mono-Methyl glutarate, mono-Methyl azelate, 3-Cyclohexanepropionic acid, palmitoleic acid, oleic acid, vaccenic acid, erucic acid, phythantic acid, or any combination thereof, for example.

When a first polymer 41 of an embodiment includes a carboxylic acid, a first reactant 51 can include a hydroxy-(C₆-C₄₀)aryl group, for example. In some embodiments, a first reactant 51 can include a structure of Formula 3:

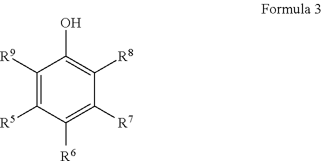

In Formula 3, R⁵⁻⁹ can be selected from the group of (C₁-C₄₀)hydrocarbyl, (C₁-C₄₀)heterohydrocarbyl, Si(R^{C})₃, P(R^{P})₂, N(R^{N})₂, OH, OR^{C}, SR^{C}, NO₂, CN, CF₃, R^{C}S(O)—, R^{C}S(O)₂—, (R^{C})₂C═N—, R^{C}C(O)O—, R^{C}OC(O)—, R^{C}C(O)N(R)—, (R^{C})₂NC(O)—, halogen atoms, hydrogen atoms, or combinations thereof, and wherein independently each R^{C} can be unsubstituted (C₁-C₁₈)hydrocarbyl, each R^{P} can be unsubstituted (C₁-C₁₈)hydrocarbyl, and each R^{N} can be unsubstituted (C₁-C₁₈)hydrocarbyl or absent, for example. When R^{N} is absent, then N can include —N═.

In some embodiments, a first reactant 51 of an embodiment can include hydroxy-aryl reactive species, which can be selected from phenol, catechol, resorcinol, hydroquinone, thymol, guaiacol, salicyl alcohol, p-cresol, o-cresol, m-cresol, 4-chlorophenol, 4-bromophenol, 2-naphthol, 4-nitrophenol, ethylphenol, propylphenol, butylphenol, tert-butylphenol, isopropylphenol, 2,6-dimethylphenol, 2,4-dimethylphenol, 3,5-dimethylphenol, 2,4,6-trimethylphenol, 2-ethylphenol, 4-ethylphenol, 2-isopropylphenol, 2-tert-butylphenol, 2-sec-butylphenol, 4-tert-butylcatechol, 3-methylcatechol, 4-(benzyloxy)phenol, 3-(dimethylamino)phenol, 4-(heptyloxy)phenol, 4-(octyloxy)phenol, 2-(benzyloxy)phenol, 4-(tert-butyldimethylsiloxy)phenol, 4-(2-methoxyethyl)phenol, 4-(2,4-dichlorophenoxy)phenol, 2-(1-pyrrolidinyl)phenol, 2-(4-bromophenoxy)phenol, 4-(4-morpholinylcarbonyl)phenol, 4-(methylmercapto)phenol, 2-(p-tolyloxy)phenol, 4-(hexadecyloxy)phenol, 4-(methoxymethyl)phenol, 4-(pentyloxy)phenol, 4-(trimethylsilyl)phenol, 4-dodecyloxy-phenol, 4-heptylsulfanyl-phenol, 2,4,6-tris(dimethylaminomethyl)phenol, 4-(1,3-thiazol-2-yl)phenol, 2-(2-pyridyl)phenol, 4-(1 h-tetrazol-5-ylmethyl)phenol, 4-(2 h-tetrazol-2-yl)phenol, 2-(1-methylbutyl)phenol, 2-(4-methylbenzyl)phenol, 3-(1-piperidinylmethyl)phenol, 3-(1-pyrrolidinylmethyl)phenol, 4-(1-adamantyl)phenol, 4-(1-indanyl)phenol, 4-(1-methylcyclohexyl)phenol, 4-(1,1-diphenylpropyl)phenol, 4-(3-hydroxyisoamyl)phenol, 2-[2-(3-methoxy-phenyl)-ethyl]-phenol, 4′-(1 h-1,2,4-triazol-1-yl)phenol, 4-(pyridin-4-yl)phenol, 2-benzyl-4-methoxy-phenol, 4-(pyridin-2-yl)phenol, 3-ethoxy-4-methoxy-phenol, 4-dimethoxymethyl-2-methoxy-phenol, 4-hex-5-enyloxy-phenol, 3-diethylaminophenol, 2,6-dimethyl-4-(1,1-dimethylpropyl)phenol, or any combination thereof, for example.

### Photoacid Generator (PAG)

In an embodiment of the present disclosure, the inventive photoresist chemical composition can comprise a PAG that can be selected from the PAGs described above.

### Solvent

In an embodiment of the present disclosure, the inventive photoresist chemical composition can comprise a solvent that can be selected from the solvents described above.

### Optional Additives

In an embodiment of the present disclosure, the inventive photoresist chemical composition can comprise an optional additive that can be selected from the optional additives described above.

### Solubility Shifting Agent

Next, some example materials that can be implemented and used for a solubility shifting agent (SSA) 15 referenced above while describing the example embodiments of FIGS. 1A to 10, and that can be implemented and used for an SSA 15 in other embodiments of the present disclosure, will be described.

An SSA 15 of an embodiment of the present disclosure can include a thermal-acid generator (TAG) that is configured to generate an acid in response to heat and/or a photo-acid generator (PAG) that is configured to generate an acid in response to actinic radiation, for example. In an embodiment, the SSA 15 can include an acid or an acid generator such as a TAG or PAG, for example.

In an embodiment, an SSA 15 can include multiple solubility shifting agents combined, such as multiple PAGs, multiple TAGs, or one or more PAGs combined with one or more TAGs, or any combination thereof with an already free acid, for example.

### Solubility Shifting Agent as a Free Acid

In some embodiments, an SSA 15 can be an acid that is an organic acid, which can include both non-aromatic acids and aromatic acids optionally having fluorine substitution. Suitable organic acids for an SSA 15 of an embodiment can include: carboxylic acids and polycarboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid, and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid; or any combination thereof, for example.

In some embodiments, an SSA 15 can be an aromatic sulfonic acid. For example, an aromatic sulfonic acid can be of general Formula 4:

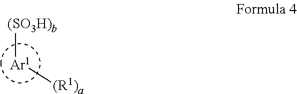

In Formula 4, Ar¹ can represent an aromatic group, which can be carbocyclic, heterocyclic, or a combination thereof. The aromatic group can be monocyclic, for example, phenyl or pyridyl, or polycyclic, for example biphenyl, and can include: plural fused aromatic rings such as naphthyl, anthracenyl, pyrenyl, or quinolinyl; or fused ring systems having both aromatic and non-aromatic rings such as 1,2,3,4-tetrahydronaphthalene, 9,10-dihydroanthracene or fluorene. A wide variety of aromatic groups may be used for Ar¹. The aromatic group typically can have from 5 to 40 carbons, preferably from 6 to 35 carbons, and more preferably from 6 to 30 carbons. Suitable aromatic groups can include, but are not limited to: phenyl, biphenyl, naphthalenyl, anthracenyl, phenanthrenyl, pyrenyl, tetracenyl, triphenylenyl, tetraphenyl, benzo[f]tetraphenyl, benzo[m]tetraphenyl, benzo[k]tetraphenyl, pentacenyl, perylenyl, benzo[a]pyrenyl, benzo[e]pyrenyl, benzo[ghi]perylenyl, coronenyl, quinolonyl, 7,8-benzoquinolinyl, fluorenyl, and 12H-dibenzo[b,h]fluorenyl. Of these, phenyl can be particularly preferred.

In Formula 4, R¹ independently can represent a halogen atom, hydroxy, substituted or unsubstituted alkyl, substituted or unsubstituted heteroalkyl, substituted or unsubstituted carbocyclic aryl, substituted or unsubstituted heterocyclic aryl, substituted or unsubstituted alkoxy, or a combination thereof. R, can also include one or more groups such as ester, carboxy, ether, or a combination thereof.

In Formula 4, “a” can represent an integer of 0 or more and “b” can represent an integer of 1 or more, provided that a+b is not greater than the total number of available aromatic carbon atoms of Ar¹. Preferably, two or more of R¹ can be independently a fluorine atom or a fluoroalkyl group bonded directly to an aromatic ring carbon atom.

The aromatic acid can be a sulfonic acid including a phenyl, biphenyl, naphthyl, anthracenyl, thiophene or furan group. The aromatic acid can be chosen from one or more aromatic sulfonic acids of the following general Formulas 5-10:

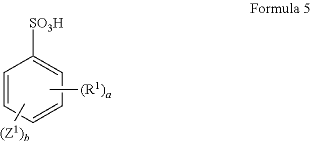

In Formula 5, R¹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 5, Z¹ can independently represent a group chosen from carboxyl, hydroxy, nitro, cyano, C1 to C5 alkoxy, formyl and sulfonic acid. In Formula 5, “a” and “b” can be independently an integer from 0 to 5, and a+b can be 5 or less.

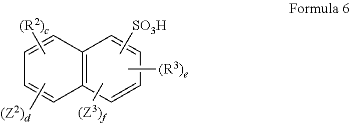

In Formula 6, R² and R³ each can independently represent a substituted or unsubstituted C1-C20 alkyl group, a substituted or unsubstituted C5-C16 aryl group, or a combination thereof, optionally containing one or more group chosen from carbonyl, carbonyloxy, sulfonamido, ether, thioether, a substituted or unsubstituted alkylene group, or a combination thereof.

In Formula 6, Z² and Z³ each can independently represent a group chosen from carboxyl, hydroxy, nitro, cyano, C1 to C5 alkoxy, formyl and sulfonic acid. In Formula 6, “c” and “d” can be independently an integer from 0 to 4, c+d can be 4 or less, “e” and “f” can be independently an integer from 0 to 3, and e+f can be 3 or less.

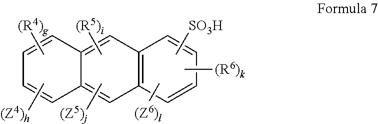

In Formula 7, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof

In Formula 7, Z⁴, Z⁵ and Z⁶ each can independently represent a group chosen from carboxyl, hydroxy, nitro, cyano, C1 to C5 alkoxy, formyl and sulfonic acid. In Formula 7, “g” and “h” can be independently an integer from 0 to 4, g+h can be 4 or less, “i” and “j” can be independently an integer from 0 to 2, i+j can be 2 or less, “k” and “l” can be independently an integer from 0 to 3, and k+l can be 3 or less.

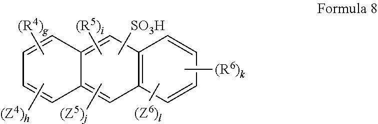

In Formula 8, R⁴, R⁵ and R⁶ each can independently represent a substituted or unsubstituted C1-C20 alkyl group, a substituted or unsubstituted C5-C12 aryl group, or a combination thereof, optionally containing one or more group chosen from carbonyl, carbonyloxy, sulfonamido, ether, thioether, a substituted or unsubstituted alkylene group, or a combination thereof.

In Formula 8, Z⁴, Z⁵ and Z⁶ each can independently represent a group chosen from carboxyl, hydroxy, nitro, cyano, C1 to C5 alkoxy, formyl and sulfonic acid. In Formula 8, “g” and “h” can be independently an integer from 0 to 4, g+h can be 4 or less, “i” and “j” can be independently an integer from 0 to 1, i+j can be 1 or less, “k” and “l” can be independently an integer from 0 to 4, and k+l can be 4 or less.

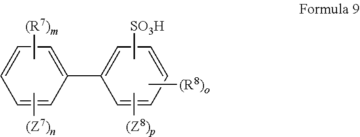

In Formula 9, R⁷ and R⁸ each can independently represent a substituted or unsubstituted C1-C20 alkyl group, a substituted or unsubstituted C5-C14 aryl group, or a combination thereof, optionally containing one or more group chosen from carboxyl, carbonyl, carbonyloxy, sulfonamido, ether, thioether, a substituted or unsubstituted alkylene group, or a combination thereof

In Formula 9, Z⁷ and Z⁸ each can independently represent a group chosen from hydroxy, nitro, cyano, C1 to C5 alkoxy, formyl and sulfonic acid. In Formula 9, “m” and “n” can be independently an integer from 0 to 5, m+n can be 5 or less, “o” and “p” can be independently an integer from 0 to 4, and o+p can be 4 or less.

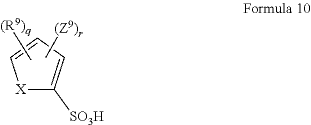

In Formula 10, X can be O or S. In Formula 10, R⁹ can independently represent a substituted or unsubstituted C1-C20 alkyl group, a substituted or unsubstituted C5-C20 aryl group, or a combination thereof, optionally containing one or more group chosen from carbonyl, carbonyloxy, sulfonamido, ether, thioether, a substituted or unsubstituted alkylene group, or a combination thereof.

In Formula 10, Z⁹ can independently represent a group chosen from carboxyl, hydroxy, nitro, cyano, C1 to C5 alkoxy, formyl and sulfonic acid. In Formula 10, “q” and “r” can be independently an integer from 0 to 3, and q+r can be 3 or less.

For each of the structures of Formulas 5-10, the R¹-R⁹ groups can optionally form a fused structure together with their respective associated rings, for example.

For an SSA 15 of an embodiment, example aromatic sulfonic acids can include, without limitation, the following:

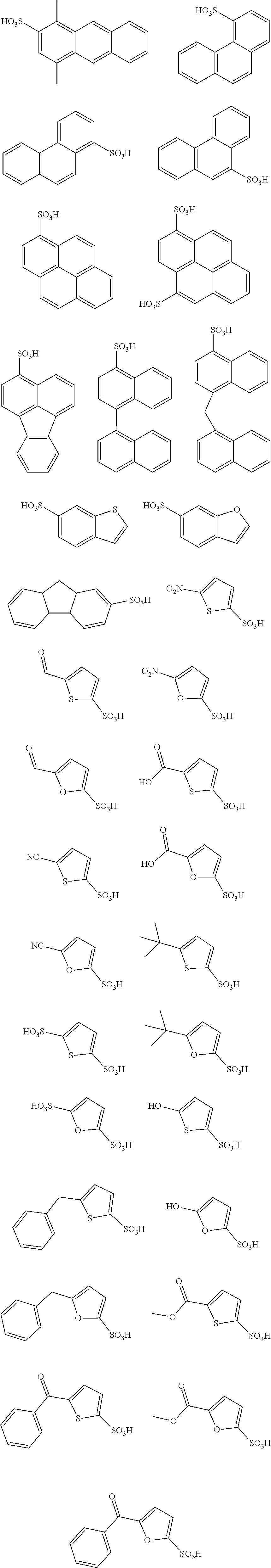

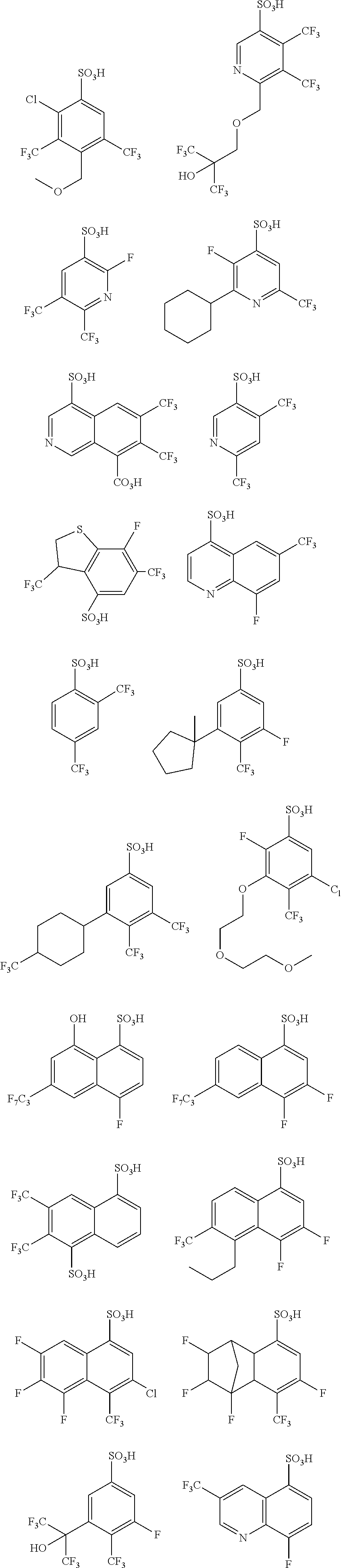

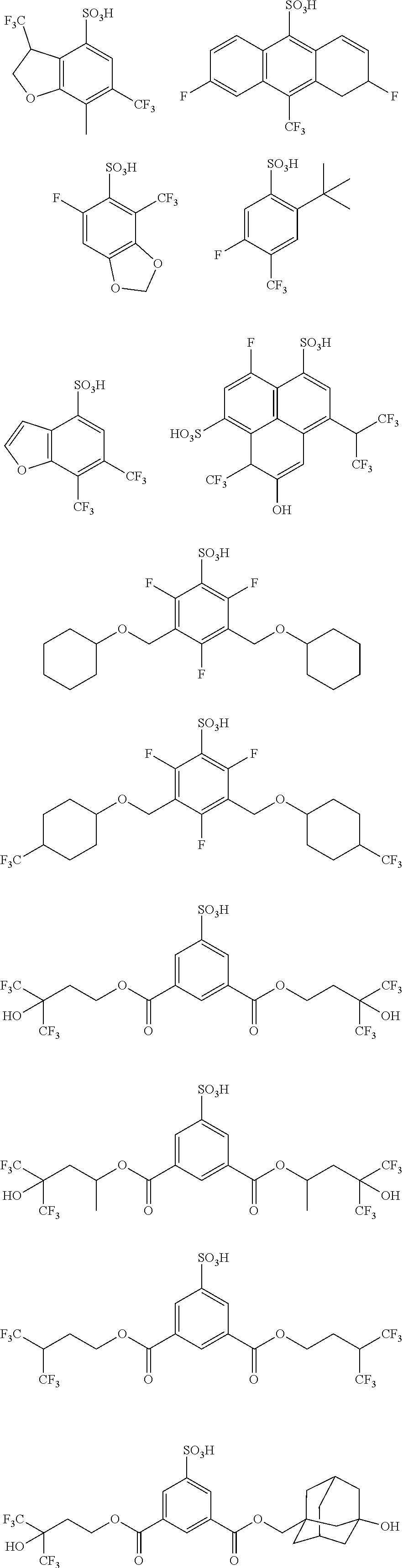

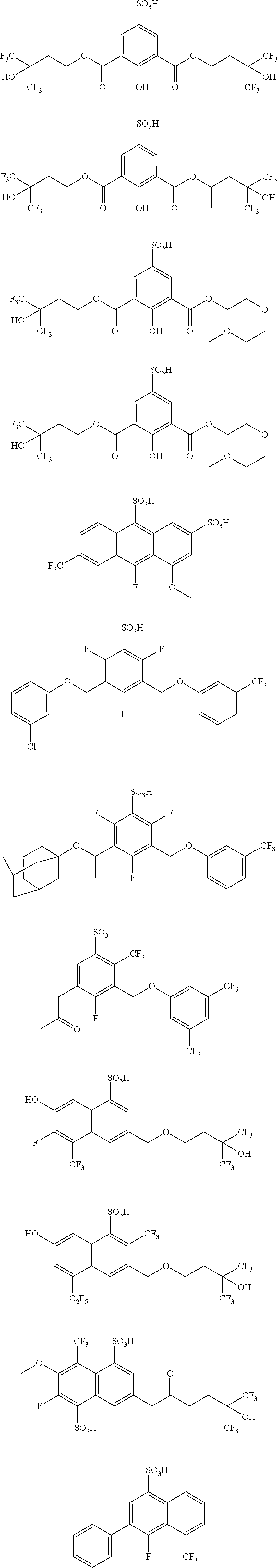

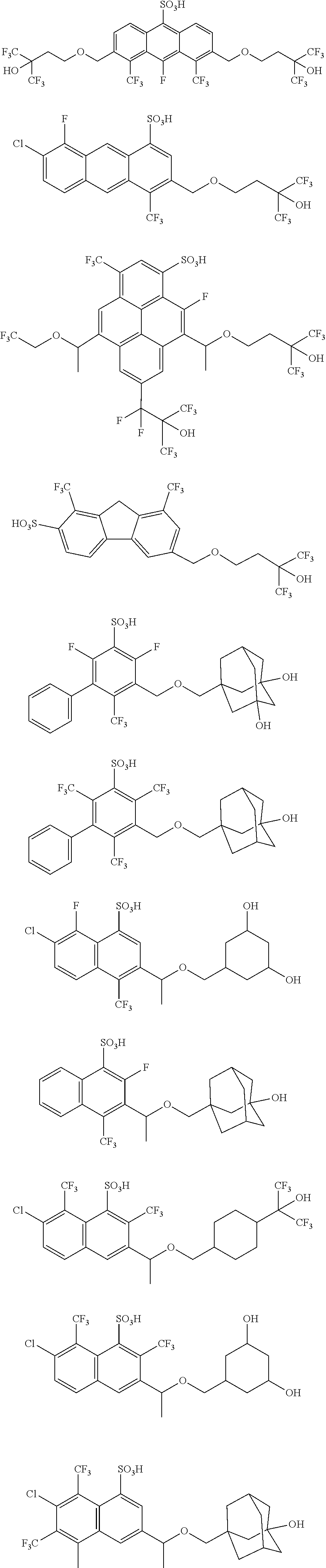

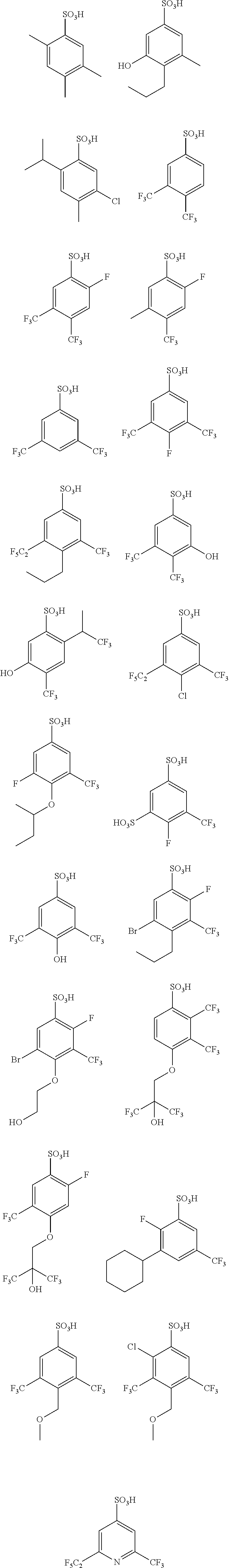

For an SSA 15 of an embodiment, example non-aromatic sulfonic acids can include, without limitation, the following:

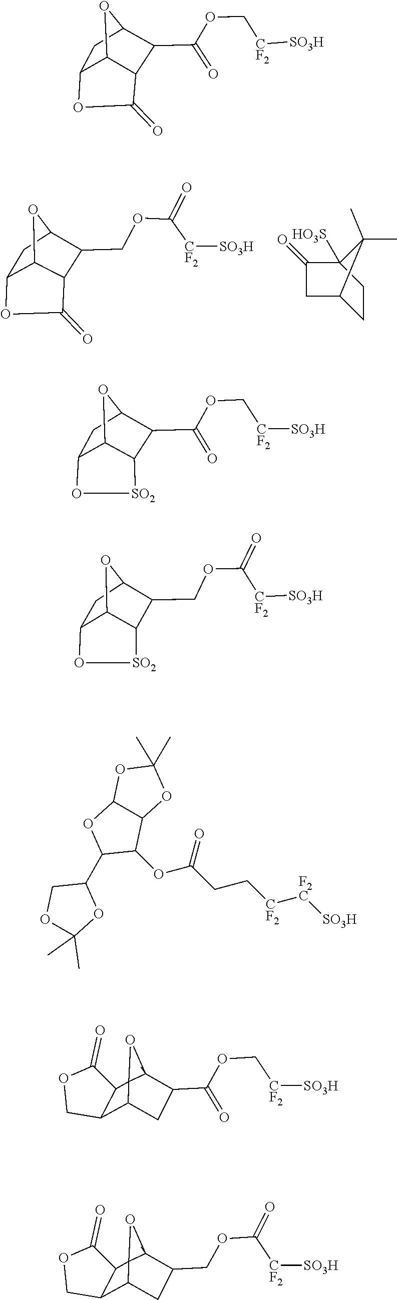

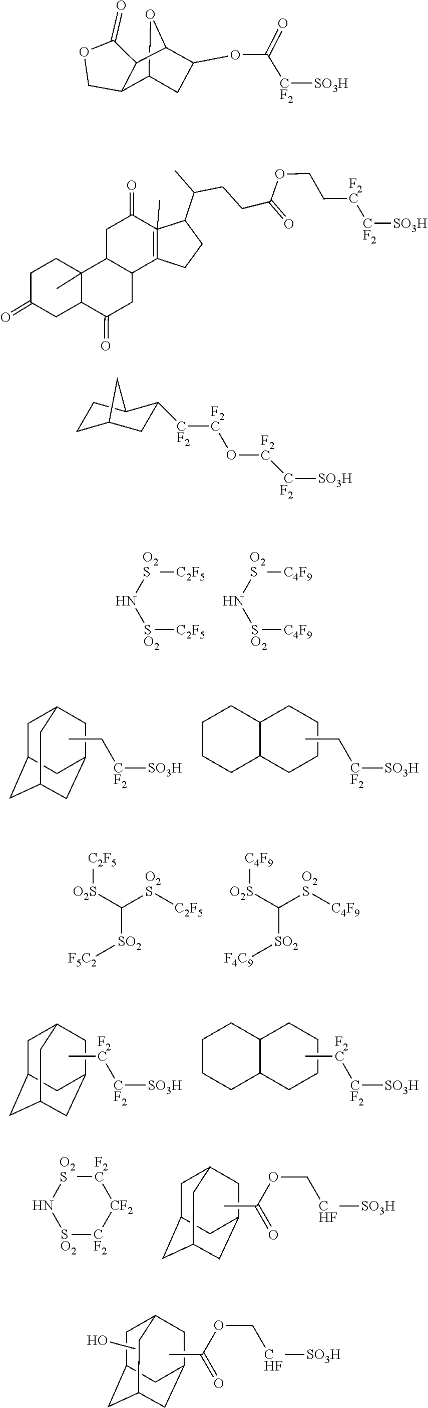

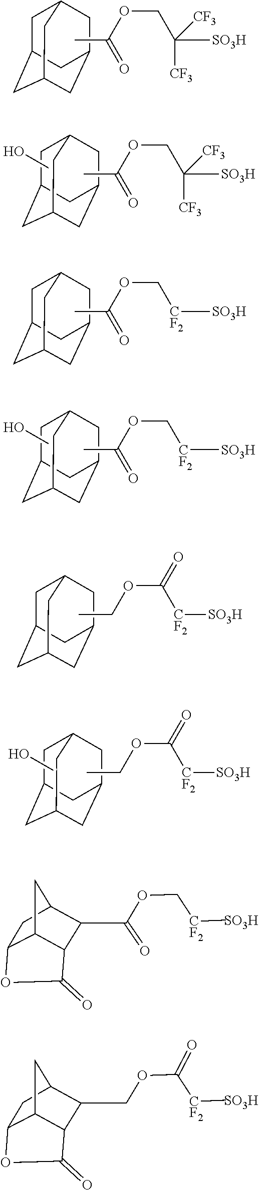

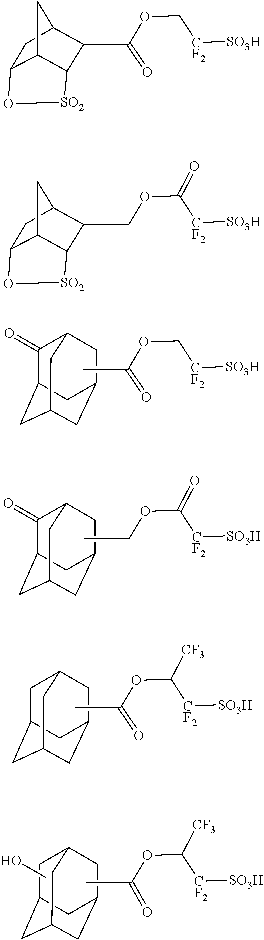

### Solubility Shifting Agent as Thermal Acid Generator (TAG)

For an SSA 15 of an embodiment, suitable thermal acid generators can include those capable of generating the acids described above. The thermal acid generator (TAG) can be non-ionic or ionic.

For an SSA 15 of an embodiment, suitable nonionic thermal acid generators can include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, or their salts, or combinations thereof.

For an SSA 15 of an embodiment, suitable ionic thermal acid generators can include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, or benzenesulfonate salts, or combinations thereof. Compounds that can generate a sulfonic acid upon activation can be generally suitable as a TAG for an SSA 15 of an embodiment, for example. For an SSA 15 of an embodiment, some preferred thermal acid generators can include p-toluenesulfonic acid ammonium salts and heteroaryl sulfonate salts, for example.

For example, for an SSA 15 of an embodiment, the TAG can be preferably ionic with a reaction scheme for generation of a sulfonic acid as shown below:

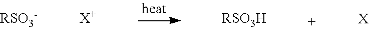

wherein RSO₃⁻ can be the TAG anion and X⁺ can be the TAG cation, preferably an organic cation. The cation can be a nitrogen-containing cation of the general Formula 11:

(BH)⁺ Formula 11

Formula 11 can be the monoprotonated form of a nitrogen-containing base B. In Formula 11, suitable nitrogen-containing bases B can include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; and nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B can be preferably a heteroaromatic base.

Base B typically can have a pKₐ from 0 to 5.0, or between 0 and 4.0, or between 0 and 3.0, or between 1.0 and 3.0. As used herein, the term “pKₐ” is used in accordance with its art-recognized meaning, that is, pKₐ can be the negative log (to the base 10) of the dissociation constant of the conjugate acid (BH)⁺ of the basic moiety (B) in aqueous solution at about room temperature. In certain embodiments, base B can have a boiling point less than about 170° C., or less than about 160° C., 150° C., 140° C., 130° C., 120° C., 110° C., 100° C., or 90° C.

For an SSA 15 of an embodiment, example suitable nitrogen-containing cations (BH)⁺ can include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

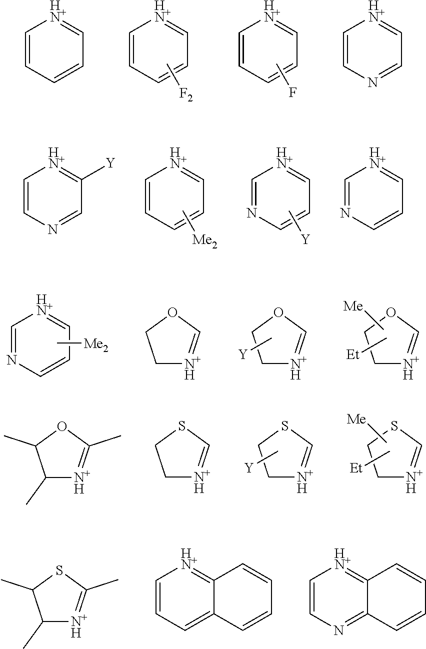

in which Y is alkyl, preferably, methyl or ethyl.

Other suitable cations can include onium cations. Suitable onium cations can include, for example, sulfonium and iodonium cations, for example, those of the following general Formula 12:

⁺X—(R¹⁰)ₛ Formula 12

In Formula 12, X can be S or I, wherein when X is I then “a” can be 2, and when X is S then “a” can be 3. In Formula 12, R¹⁰ can be independently chosen from organic groups such as optionally substituted C₁₋₃₀ alkyl, polycyclic or monocyclic C₃₋₃₀ cycloalkyl, polycyclic or monocyclic C₆₋₃₀ aryl, or a combination thereof, wherein when X is S, two of the R groups together optionally form a ring.

For an SSA 15 of an embodiment, example suitable sulfonium and iodonium cations include the following:

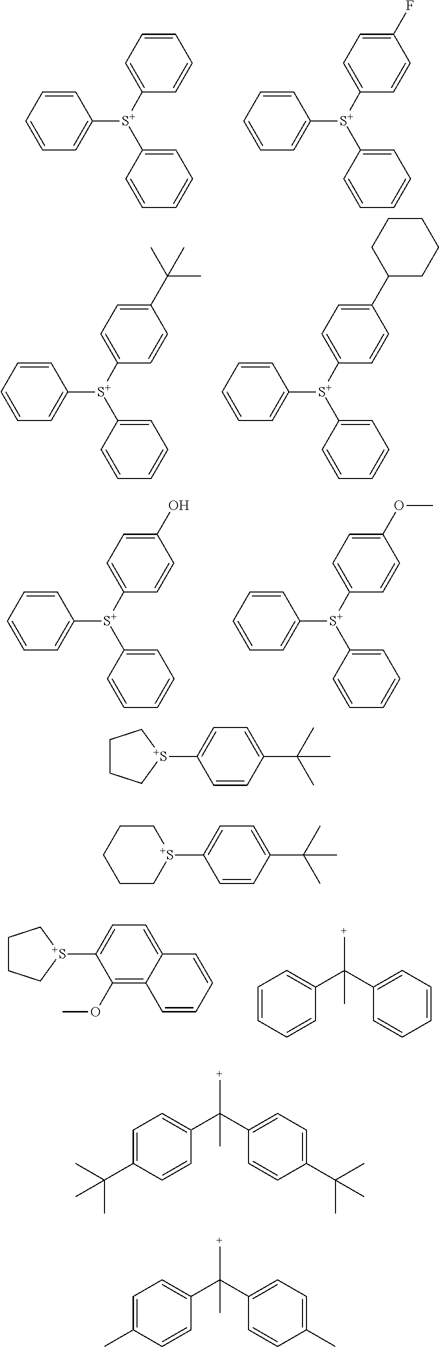

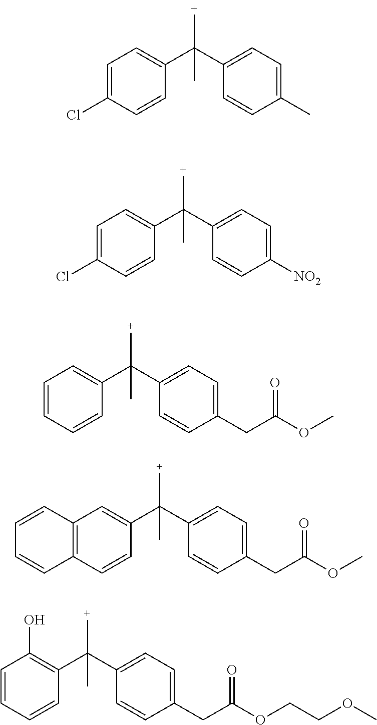

### Solubility Shifting Agent as Photoacid Generator (PAG)

For an SSA 15 of an embodiment, suitable photoacid generators can include those capable of generating the acids described above in the Photoacid Generator (PAG) section for the photoresist composition descriptions, for example, which can also be used in an embodiment where the SSA 15 is brought in via an overcoat layer 106 (see, e.g., FIG. 3B). For an SSA 15 of an embodiment, a choice of PAG can be based upon such factors as acidity, catalytic activity, volatility, diffusivity, and solubility.

### Overcoat Comprising Solubility Shifting Agent

In an embodiment of present disclosure, a composition of an overcoat 106 (see, e.g., FIG. 3B) can be a composition that can include a second polymer, an SSA 15, a solvent, and may also contain additional optional components, which can also apply to a first intermediate structure 11 of FIG. 1A, for example.

### Second Polymer

In some embodiments, the second polymer of a first intermediate structure 11 or of an overcoat 106 may include a matrix polymer. Any matrix polymer commonly used in the art may be included in the solubility-shifting material. The matrix polymer should have good solubility in a solvent that does not dissolve the first patterned photoresist layer 101 (see, e.g., FIGS. 3A and 3B). The matrix polymer can be formed from one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; maleic anhydride; maleimides; norbonenes; or any combination thereof.

In some embodiments, the second polymer contains one or more functional groups chosen, for example, from hydroxy, acid groups such as carboxyl, sulfonic acid and sulfonamide, silanol, fluoroalcohol such as hexafluoroisopropyl alcohol [—C(CF₃)₂OH], anhydrates, lactones, esters, ethers, allylamine, pyrrolidones and combinations thereof. The second polymer can be a homopolymer or a copolymer having a plurality of distinct repeat units, for example, two, three, four or more distinct repeat units. In one aspect, the repeat units of the second polymer are all formed from (meth)acrylate monomers, are all formed from (vinyl)aromatic monomers or are all formed from (meth) acrylate monomers and (vinyl) aromatic monomers. When the second polymer includes more than one type of repeat unit, it typically takes the form of a random copolymer.

In particular embodiments, the matrix polymer may be a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, a PHS/methacrylate (MA) copolymer, or any combination thereof.

The overcoat compositions typically include a single polymer but can optionally include one or more additional polymers. The content of the second polymer in the composition can depend, for example, on the target thickness of the layer, with a higher polymer content being used when thicker layer is desired. The second polymer is typically present in the overcoat composition in an amount of from 80 to 99.9 wt %, more typically from 90 to 99 wt %, or 95 to 99 wt %, based on total solids of the overcoat compositions, for example. The weight average molecular weight (Mw) of the polymer is typically less than 400,000, preferably from 3000 to 50,000, more preferably from 3000 to 25,000, as measured by GPC versus polystyrene standards. Typically, the second polymer will have a polydispersity index (PDI=Mw/Mn) of 3 or less, preferably 2 or less, as measured by GPC versus polystyrene standards, for example.

Suitable second polymers for use in the overcoat compositions are commercially available and/or can readily be made by persons skilled in the art. For example, the second polymer may be synthesized by dissolving selected monomers corresponding to units of the second polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

In one or more embodiments, an overcoat composition includes an active material (z.e., an acid, acid generator, base, or base generator), a solvent, and a matrix polymer as previously described. A typical formulation for such overcoat composition may include about 1 to 10 wt % solids and go to 99 wt % solvent, based on the total weight of the overcoat composition, where the solids include the active material and the matrix polymer. Within the solids content, the active material may be included in an amount ranging from about 1 to about 5 wt %, for example.

### SSA

In an embodiment of the present disclosure, the Overcoat Comprising Solubility Shifting Agent can comprise an SSA that can be selected from the SSAs described above.

### Solvent

In an embodiment of the present disclosure, the Overcoat Comprising Solubility Shifting Agent can comprise a solvent. The solvent may be any suitable solvent that facilitates dissolution of the components of the composition, provided that it does not dissolve the composition on which it is being coated (e.g., the mandrel 102). The solvent is typically chosen from water, organic solvents, and mixtures thereof. In some embodiments, the solvent may include an organic-based solvent system comprising one or more organic solvents. The term “organic-based” means that the solvent system includes greater than 50 wt % organic solvent based on total solvents of the overcoat composition, more typically greater than go wt %, greater than 95 wt %, greater than 99 wt % or 100 wt % organic solvents, based on total solvents of the overcoat compositions. The solvent component is typically present in an amount of from 90 to 99 wt % based on the overcoat composition.

Suitable organic solvents for the overcoat composition include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C4-C9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C5-C9 fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether, and mixtures containing one or more of these solvents.

The solvent included in the overcoat composition may depend on the composition and tone of the first resist. When the first resist is formed from a (meth)acrylate polymer, as is typical for ArF resists, and the resist is developed as a PTD resist, the solvent system preferably comprises one or more polar organic solvents. For example, a solubility-shifting agent meant to be absorbed into a PTD first resist may include a polar solvent such as methyl isobutyl carbinol (MIBC). The overcoat composition may also include aliphatic hydrocarbons, esters, and ethers as cosolvents such as, for example, decane, isobutyl isobutyrate, isoamyl ether, and combinations thereof. In particular embodiments, the solvent includes MIBC and a cosolvent. In such embodiments, the MIBC may be included in the solvent in an amount ranging from 60 to 99%, based on the total volume of solvent. Accordingly, the cosolvent may be included in amount ranging from 1 to 40%, based on the total volume of solvent.

When the first resist is formed from a vinyl aromatic-based polymer, as is typical for KrF and EUV photoresists, and the resist is developed as a PTD resist, the solvent system preferably comprises one or more non-polar organic solvents. The term “non-polar organic-based” means that the solvent system includes greater than 50 wt % of combined non-polar organic solvents based on total solvents of the overcoat composition, more typically greater than 70 wt %, greater than 85 wt % or 100 wt %, combined non-polar organic solvents, based on total solvents of the overcoat composition. The non-polar organic solvents are typically present in the solvent system in a combined amount of from 70 to 98 wt %, preferably 80 to 95 wt %, more preferably from 85 to 98 wt %, based on the solvent system.

Suitable non-polar solvents include, for example, ethers, hydrocarbons, and combinations thereof, with ethers being preferred. Suitable ether solvents include, for example, alkyl monoethers and aromatic monoethers, particularly preferred of which are those having a total carbon number of from 6 to 16. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

In some embodiments, the solvent system further includes one or more alcohol and/or ester solvents. For certain compositions, an alcohol and/or ester solvent may provide enhanced solubility with respect to the solid components of the composition. Suitable alcohol solvents include, for example: straight, branched or cyclic C4-9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C5-9 fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C4-9 monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent system are typically present in a combined amount of from 2 to 50 wt %, more typically in an amount of from 2 to 30 wt %, based on the solvent system.

The solvent system can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the solvent system.

When the first resist is formed from a vinyl aromatic-based polymer, a particularly preferred organic-based solvent system includes one or more monoether solvents in a combined amount of from 70 to 98 wt % based on the solvent system, and one or more alcohol and/or ester solvents in a combined amount of from 2 to 30 wt % based on the solvent system. The solvent system is typically present in the overcoat composition in an amount of from 90 to 99 wt %, preferably from 95 to 99 wt %, based on the overcoat composition.

In embodiments in which the first resist is a negative tone development (NTD) resist, suitable organic solvents include, but are not limit to, n-butyl acetate, 2-heptanone, propylene glycol methyl ether, propylene glycol methyl ether acetate, and combinations thereof.

Overcoat with First Polymer and First Reactant and/or Overcoat without SSA or PAG

In an embodiment of present disclosure, a composition of the overcoat 106 of FIG. 2B can be made with a starting overcoat chemical composition that can include a first polymer 41, a first reactant 41, a solvent, and may also contain additional optional components, which can also apply to the second intermediate structure 21 of FIG. 1A, for example. Because in some embodiments, the PAG, TAG, or SSA can be provided from an adjacent structure (e.g., first intermediate structure 11 of FIG. 1A) (e.g., first patterned photoresist layer 101 of FIG. 2B) (e.g., for an anti-spacer process flow), the overcoat can omit the PAG, TAG, SSA, or any combination thereof.

The Overcoat with First Polymer and First Reactant and/or Overcoat without SSA or PAG can comprises a solvent that may be selected from the solvents listed above for the Overcoat Comprising Solubility Shifting Agent. The solvent may be any suitable solvent that facilitates dissolution of the components of the composition, provided that it does not dissolve the composition on which it is being coated (e.g. mandrel 102). During deposition of the initial overcoat chemical composition in an embodiment, most of or all of the solvent can be evaporated, such that after deposition the overcoat 106 has little, negligible, or no solvent remaining. Such solvent can aid in the deposition operation, and preferably the matrix polymer being or including the first polymer 41 should have good solubility in such solvent, where such solvent does not dissolve the first patterned photoresist layer 101 during deposition of the overcoat 106 (see, e.g., FIG. 2A). Such composition of a starting overcoat chemical composition that includes a first polymer 41, a first reactant 41, a solvent, and may also contain additional optional components, without a PAG, TAG, or SSA, can be an inventive overcoat chemical composition.

In accordance with an embodiment of the present disclosure, a chemical composition for an overcoat material configured to be used in semiconductor manufacturing (e.g., anti-spacer process flow) can comprise a starting overcoat chemical composition that includes a first polymer, a first reactant, a solvent, and may also contain additional optional components, without a PAG, TAG, or SSA, wherein the starting overcoat chemical composition is configured such that after deposition to form an overcoat layer, the overcoat layer is insoluble in a developer containing an organic solvent and is soluble in a developer containing a quaternary ammonium hydroxide in an aqueous solution.

### Developers

In an embodiment of the present disclosure, a developer that contains an organic solvent can include an organic solvent conventionally used in the manufacture of electronic devices. In an embodiment of the present disclosure, a developer that contains an organic solvent can include, for example: aliphatic hydrocarbons such as hexane and heptane; aromatic hydrocarbons such as toluene and xylene; halogenated hydrocarbons such as dichloromethane, 1,2-dichloroethane and 1-chlorohexane; alcohols such as methanol, ethanol, 1-propanol, iso-propanol, tert-butanol, 2-methyl-2-butanol and 4-methyl-2-pentanol; propylene glycol monomethyl ether (PGME), ethers such as diethyl ether, tetrahydrofuran, 1,4-dioxane and anisole; ketones such as acetone, methyl ethyl ketone, methyl iso-butyl ketone, 2-heptanone and cyclohexanone (CHO); esters such as ethyl acetate, n-butyl acetate, propylene glycol monomethyl ether acetate (PGMEA), ethyl lactate (EL), hydroxyisobutyrate methyl ester (HBM) and ethyl acetoacetate; lactones such as gamma-butyrolactone (GBL) and epsilon-caprolactone; lactams such as N-methyl pyrrolidone; nitriles such as acetonitrile and propionitrile; cyclic or non-cyclic carbonate esters such as propylene carbonate, dimethyl carbonate, ethylene carbonate, propylene carbonate, diphenyl carbonate, and propylene carbonate; polar aprotic solvents such as dimethyl sulfoxide and dimethyl formamide; and combinations thereof, for example. Of these, some preferred organic solvents can be PGME, PGMEA, EL, GBL, HBM, CHO, or combinations thereof, for example.

The exposed photoresist layer may be developed with either a positive tone development (PTD) or negative tone development (NTD) process. However, unlike conventional PTD and NTD processes, in an embodiment of the present disclosure, the exposed photoresist layer can be now soluble in organic solvents and insoluble in aqueous base developers. In an embodiment, suitable developers for an PTD process can be organic solvent-based, which can mean the cumulative content of organic solvents in the developer is 50 wt % or more, typically 95 wt % or more, 98 wt % or more, or 100 wt %, based on total weight of the developer. For an embodiment, suitable organic solvents for the PTD developer can include, for example, those chosen from ketones, esters, ethers, hydrocarbons, and mixtures thereof. In an embodiment, a developer can be typically 2-heptanone or n-butyl acetate.

Conversely, in an embodiment, suitable developers for an NTD process can include aqueous base developers, for example, quaternary ammonium hydroxide solutions such as tetramethylammonium hydroxide (TMAH), preferably 0.26 normal (N) TMAH, tetraethylammonium hydroxide, tetrabutylammonium hydroxide, sodium hydroxide, potassium hydroxide, sodium carbonate, potassium carbonate, and the like, for example.

For an embodiment, a solvent can be any suitable solvent provided that it does not dissolve a first photoresist intended to remain (e.g., for an anti-spacer pattern). For an embodiment, a solvent can be typically chosen from water, organic solvents, and mixtures thereof. In some embodiments, a solvent can include an organic-based solvent system including one or more organic solvents. The term “organic-based” can indicate that the solvent system includes greater than 50 wt % organic solvent based on total solvents of a given composition, more typically greater than 90 wt %, greater than 95 wt %, greater than 99 wt % or 100 wt % organic solvents, based on total solvents of the compositions. In an embodiment, a solvent component can be typically present in an amount of from 90 to 99 wt % based on the composition.

In an embodiment, suitable organic solvents for a developer can include, for example: alkyl esters such as alkyl propionates such as n-butyl propionate, n-pentyl propionate, n-hexyl propionate and n-heptyl propionate, and alkyl butyrates such as n-butyl butyrate, isobutyl butyrate and isobutyl isobutyrate; ketones such as 2,5-dimethyl-4-hexanone and 2,6-dimethyl-4-heptanone; aliphatic hydrocarbons such as n-heptane, n-nonane, n-octane, n-decane, 2-methylheptane, 3-methylheptane, 3,3-dimethylhexane and 2,3,4-trimethylpentane, and fluorinated aliphatic hydrocarbons such as perfluoroheptane; alcohols such as straight, branched or cyclic C4-C9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol and 4-octanol; 2,2,3,3,4,4-hexafluoro-1-butanol, 2,2,3,3,4,4,5,5-octafluoro-1-pentanol and 2,2,3,3,4,4,5,5,6,6-decafluoro-1-hexanol, and C5-C9 fluorinated diols such as 2,2,3,3,4,4-hexafluoro-1,5-pentanediol, 2,2,3,3,4,4,5,5-octafluoro-1,6-hexanediol and 2,2,3,3,4,4,5,5,6,6,7,7-dodecafluoro-1,8-octanediol; ethers such as isopentyl ether and dipropylene glycol monomethyl ether; or mixtures containing one or more of these solvents, for example.

In an embodiment, a solvent included in a developer may depend on a composition and tone of a first intermediate structure 11. When a first intermediate structure 11 is formed from a (meth)acrylate polymer, as is typical for ArF resists, and the resist can be developed as a PTD resist, and the solvent system can include one or more polar organic solvents. For example, a polar solvent can include methyl isobutyl carbinol (MIBC). A developer containing an organic solvent can also include aliphatic hydrocarbons, esters, and ethers as cosolvents such as, for example, decane, isobutyl isobutyrate, isoamyl ether, and combinations thereof. In some embodiments, an organic solvent can include MIBC and a cosolvent. In such embodiments, the MIBC can be included in the solvent in an amount ranging from 60 to 99%, based on the total volume of solvent. Accordingly, the cosolvent can be included in amount ranging from 1 to 40%, based on the total volume of solvent.

When a first intermediate structure 11 is formed from a vinyl aromatic-based polymer, as is typical for KrF and EUV photoresists, and the resist can be developed as a PTD resist, and developer can contain a solvent system including one or more non-polar organic solvents. The term “non-polar organic-based” can indicate that the solvent system includes greater than 50 wt % of combined non-polar organic solvents based on total solvents of the composition, more typically greater than 70 wt %, greater than 85 wt % or 100 wt %, combined non-polar organic solvents, based on total solvents of the composition. The non-polar organic solvents can be typically present in the solvent system in a combined amount of from 70 to 98 wt %, preferably 80 to 95 wt %, more preferably from 85 to 98 wt %, based on the solvent system, for example.

In an embodiment, suitable non-polar solvents for a developer can include, for example, ethers, hydrocarbons, and combinations thereof, with ethers being sometimes preferred. In an embodiment, suitable ether solvents for a developer can include, for example, alkyl monoethers and aromatic monoethers, particularly preferred of which can be those having a total carbon number of from 6 to 16. In an embodiment, suitable alkyl monoethers can include, for example, 14-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. In an embodiment, suitable aromatic monoethers can include, for example, anisole, ethylbenzyl ether, diphenyl ether, dibenzyl ether and phenetole, with anisole being preferred. In an embodiment, suitable aliphatic hydrocarbons can include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. In an embodiment, suitable aromatic hydrocarbons can include, for example, benzene, toluene, and xylene.

In some embodiments, the solvent system of a developer can further include one or more alcohol and/or ester solvents. For certain compositions, an alcohol and/or ester solvent can provide enhanced solubility with respect to the solid components of the composition. In an embodiment, suitable alcohol solvents can include, for example: straight, branched or cyclic C4-9 monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C5-9 fluorinated diols such as 2,2,3,3,4,4-hexafluoro-1,5-pentanediol, 2,2,3,3,4,4,5,5-octafluoro-1,6-hexanediol, or 2,2,3,3,4,4,5,5,6,6,7,7-dodecafluoro-1,8-octanediol. In an embodiment, an alcohol solvent can be preferably a C4-9 monohydric alcohol, with 4-methyl-2-pentanol being preferred. In an embodiment, suitable ester solvents can include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in a solvent system for a developer of an embodiment, can be typically present in a combined amount of from 2 to 50 wt %, more typically in an amount of from 2 to 30 wt %, based on the solvent system, for example.

In an embodiment, a solvent system for a developer can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, can be typically present in a combined amount of from 1 to 20 wt % based on the solvent system.

In an embodiment, when a first intermediate structure 11 is formed from a vinyl aromatic-based polymer, a particularly preferred organic-based solvent system for a developer can include one or more monoether solvents in a combined amount of from 70 to 98 wt % based on the solvent system, and one or more alcohol and/or ester solvents in a combined amount of from 2 to 30 wt % based on the solvent system. The solvent system can be typically present in a developer in an amount of from 90 to 99 wt %, preferably from 95 to 99 wt %, based on the developer composition, for example. In an embodiment in which a first intermediate structure 11 is a NTD resist, a suitable organic solvent can include, but is not limit to, n-butyl acetate, 2-heptanone, propylene glycol methyl ether, propylene glycol methyl ether acetate, and combinations thereof, for example.

### Quencher

In some embodiments, a quencher base or base generator can be included in the second intermediate structure 21 to help control diffusion of an active material in/of the SSA 15, for example. In some embodiments, a quencher can be an additional optional component 99 (see, e.g., FIG. 3F), for example. For an embodiment, suitable quencher base or base generators can include, but are not limited to, hydroxides, carboxylates, amines, imines, amides, or mixtures thereof. Specific examples of bases can include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, or combinations thereof. Amines can include aliphatic amines, cycloaliphatic amines, aromatic amines, or heterocyclic amines. The amine can be a primary, secondary, or tertiary amine. The amine can be a monoamine, diamine, or polyamine. Suitable amines can include C1-30 organic amines, imines, or amides, or may be a C1-30 quaternary ammonium salt of a strong base (e.g., a hydroxide or alkoxide) or a weak base (e.g., a carboxylate). In some embodiments, example bases can include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl)propane, Troger's base, a hindered amine such as diazabicycloundecene (DBU) or diazabicyclononene (DBN), amides like tert-buty 1,3-dihydroxy-2-(hydroxymethyl)propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate.

In some embodiments, the amine can be a hydroxyamine. Examples of hydroxyamines can include hydroxyamines having one or more hydroxyalkyl groups each having 1 to about 8 carbon atoms, and sometimes preferably 1 to about 5 carbon atoms such as hydroxymethyl, hydroxyethyl and hydroxybutyl groups. Specific examples of hydroxy amines can include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol, and triethanolamine.

In an embodiment, suitable base generators can be thermal base generators. A thermal base generator (TAG) can form a base upon heating above a first temperature, typically about 140° C. or higher. The thermal base generator can include a functional group such as an amide, sulfonamide, imide, imine, O-acyl oxime, benzoyloxycarbonyl derivative, quarternary ammonium salt, nifedipine, carbamate, or combinations thereof, for example.

In an embodiment, example thermal base generators can include:
0-{(.beta.-(dimethylamino)ethyl)aminocarbonyl}benzoic acid,
0-{(.gamma.-(dimethylamino)propyl)aminocarbonyl}benzoic acid,
2,5-bis{(.beta.-(dimethylamino)ethyl)aminocarbonyl}terephthalic acid,
2,5-bis {(.gamma.-(dimethylamino)propyl)aninocarbonyl}terephthalic acid,
2,4-bis{(.beta.-(dimethylamino)ethyl)aminocarbonyl}isophthalic acid,
2,4-bis{(.gamma.-(dimethylamino)propyl)aminocarbonyl]isophthalic acid, or combinations thereof, for example.

A quencher base or base generator can be in non-polymeric or polymer-bound form. When in polymeric form, a quencher can be present in polymerized units on the polymer. The polymerized units containing the quencher can be typically present in an amount of from 0.1 to 30 mole %, preferably from 1 to 10 mole %, and more preferably from 1 to 2 mole %, based on total repeating units of the polymer.

### Optional Additives

In an embodiment, a composition described above may further include one or more additional, optional additives (e.g., additional optional component 99 in FIG. 3F). For example, optional additives may include actinic and contrast dyes, anti-striation agents, plasticizers, speed enhancers, sensitizers, photo-decomposable quenchers (also known as photo-decomposable bases), basic quenchers, surfactants, and the like, or combinations thereof. If present, the optional additives can be typically present in the photoresist compositions in an amount from 0.01 to 10 wt %, based on total solids of the photoresist composition.

Photo-decomposable quenchers can generate a weak acid upon irradiation. The acid generated from a photo-decomposable quencher can be not strong enough to react rapidly with acid-labile groups that are present in the resist matrix. Example photo-decomposable quenchers can include, for example, photo-decomposable cations, and can be preferably those also useful for preparing strong acid generator compounds, paired with an anion of a weak acid (pKₐ>−1) such as, for example, an anion of a C₁₋₂₀ carboxylic acid or C₁₋₂₀ sulfonic acid.

Example carboxylic acids can include formic acid, acetic acid, propionic acid, tartaric acid, succinic acid, cyclohexanecarboxylic acid, benzoic acid, salicylic acid, and the like. Example sulfonic acids can include p-toluene sulfonic acid, camphor sulfonic acid and the like. In some embodiments, the photo-decomposable quencher can be a photo-decomposable organic zwitterion compound such as diphenyliodonium-2-carboxylate.

The photo-decomposable quencher can be in non-polymeric or polymer-bound form. When in polymeric form, the photo-decomposable quencher can be present in polymerized units on the first polymer or second polymer. The polymerized units containing the photo-decomposable quencher can be typically present in an amount from 0.1 to 30 mole %, sometimes preferably from 1 to 10 mole %, and sometimes more preferably from 1 to 2 mole %, based on total repeating units of the polymer.

Example basic quenchers can include, for example: linear aliphatic amines such as tributylamine, trioctylamine, triisopropanolamine, tetrakis(2-hydroxypropyl)ethylenediamine:n-tert-butyldiethanolamine, tris(2-acetoxy-ethyl) amine, 2,2′,2″,2′″-(ethane-1,2-diylbis(azanetriyl))tetraethanol, 2-(dibutylamino)ethanol, and 2,2′,2″-nitrilotriethanol; cyclic aliphatic amines such as 1-(tert-butoxycarbonyl)-4-hydroxypiperidine, tert-butyl 1-pyrrolidinecarboxylate, tert-butyl 2-ethyl-1H-imidazole-1-carboxylate, di-tert-butyl piperazine-1,4-dicarboxylate, and N-(2-acetoxy-ethyl)morpholine; aromatic amines such as pyridine, di-tert-butyl pyridine, and pyridinium; linear and cyclic amides and derivatives thereof such as N,N-bis(2-hydroxyethyl)pivalamide, N,N-diethylacetamide, N¹,N¹,N³,N³-tetrabutylmalonamide, 1-methylazepan-2-one, 1-allylazepan-2-one, and tert-butyl 1,3-dihydroxy-2-(hydroxymethyl)propan-2-ylcarbamate; ammonium salts such as quaternary ammonium salts of sulfonates, sulfamates, carboxylates, and phosphonates; imines such as primary and secondary aldimines and ketimines; diazines such as optionally substituted pyrazine, piperazine, and phenazine; diazoles such as optionally substituted pyrazole, thiadiazole, and imidazole; or optionally substituted pyrrolidones such as 2-pyrrolidone and cyclohexyl pyrrolidine.

The basic quenchers can be in non-polymeric or polymer-bound form. When in polymeric form, the quencher can be present in polymerized units on the polymer. The polymerized units containing the quencher can be typically present in an amount of from 0.1 to 30 mole %, sometimes preferably from 1 to 10 mole %, and sometimes more preferably from 1 to 2 mole %, based on total repeating units of the polymer.

Example surfactants can include fluorinated and non-fluorinated surfactants and can be ionic or non-ionic, with non-ionic surfactants being sometimes preferable. Example fluorinated non-ionic surfactants can include perfluoro C₄ surfactants such as FC-4430 and FC-4432 surfactants, available from 3M Corporation; and fluorodiols such as POLYFOX PF-636, PF-6320, PF-656, and PF-6520 fluorosurfactants from Omnova. In some embodiments, the photoresist composition can further include a surfactant polymer including a fluorine-containing repeating unit.

More example embodiments of the present disclosure are summarized here. Other embodiments can also be understood from the entirety of the specification as well as the claims filed herein.

Example 1. A method for forming a patterned mask, the method including: providing a first intermediate structure on a substrate, where the first intermediate structure includes a first material, where the first material includes a solubility shifting agent therein, and where the first material is insoluble in a first developer containing an organic solvent; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent; and diffusing at least a catalyst portion of the solubility shifting agent from the first material into the first region of the second intermediate structure and chemically transforming the first region of the second intermediate structure to a converted region of a third material to a first depth into the second intermediate structure using the catalyst portion of the solubility shifting agent as a chemical reaction catalyst, such that the third material is soluble in the first developer containing the organic solvent.

Example 2. The method of example 1, further including removing the converted region using the organic solvent of the first developer to form an anti-spacer pattern including remaining portions of the first intermediate structure and the second intermediate structure having an opening to the substrate corresponding to the converted region and where at least part of the opening has a critical dimension corresponding to the first depth.

Example 3. The method of one of examples 1 or 2, further including depositing the second intermediate structure over the first intermediate structure, where the first intermediate structure includes a first patterned photoresist layer, where the second intermediate structure includes a first overcoat layer.

Example 4. The method of one of examples 1 to 3, further including depositing the first intermediate structure over the second intermediate structure, where the second intermediate structure includes a first patterned photoresist layer, where the first intermediate structure includes a first overcoat layer.

Example 5. The method of one of examples 1 to 4, where each of the first material and the second material is soluble in a second developer containing a quaternary ammonium hydroxide in an aqueous solution, and where the third material is insoluble in the second developer.

Example 6. The method of one of examples 1 to 5, where the first polymer includes para-hydroxystyrene, acrylic acid, methacrylic acid, 2-hydroxyethyl acrylate, 2-hydroxyethyl methacrylate, an acrylate or methacrylate functionalized with a carbohydrate, or any combination thereof.

Example 7. The method of one of examples 1 to 6, where the first polymer includes p-hydroxystyrene and the first reactant includes a carboxylic acid.

Example 8. The method of one of examples 1 to 7, where the solubility shifting agent includes a free acid that is free of fluorine.

Example 9. The method of one of examples 1 to 8, where the free acid includes trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, or any combination thereof.

Example 10. The method of one of examples 1 to 9, where the solubility shifting agent includes a thermal acid generator that is free of fluorine.

Example 11. The method of one of examples 1 to 10, where the thermal acid generator includes pyridinium perfluorobutanesulfonate, 3-fluoropyridinium perfluorobutanesulfonate, triethylammonium perfluorobutanesulfonate, 3-fluoropyridinium perfluorobutanesulfonate, pyridinium p-toluenesulfonate, 3-fluoropyridinium p-toluenesulfonate, Triethylammonium p-toluenesulfonate, trioctylammonium p-toluenesulfonate, pyridinium 4-dodecylbenzenesulfonate, 3-fluoropyridinium 4-dodecylbenzenesulfonate, triethylammonium 4-dodecylbenzenesulfonate, trioctylammonium 4-dodecylbenzenesulfonate, or any combination thereof.

Example 12. The method of one of examples 1 to 11, where the solubility shifting agent includes a photoacid generator that is free of fluorine.

Example 13. The method of one of examples 1 to 12, where the photoacid generator includes 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, or any combination thereof.

Example 14. The method of one of examples 1 to 13, where the organic solvent includes propylene glycol methyl ether acetate, propylene glycol methyl ether, N-butyl acetate, 2-heptanone, methyl isobutyl carbinol, isoamyl alcohol, n-butanol, isoamyl ether, cyclohexanone, ethyl lactate, methyl isobutyl ketone, methyl 2-hydroxyisobutyrate, or any combination thereof.

Example 15. The method of one of examples 1 to 14, where the second material of the second intermediate structure further includes a quencher.

Example 16. The method of one of examples 1 to 15, where the first region of the second intermediate structure including the second material is adjacent and in direct physical contact with the first material of the first intermediate structure.

Example 17. The method of one of examples 1 to 16, where the first material and the second material are soluble in a second developer containing a quaternary ammonium hydroxide in an aqueous solution, and where the third material is insoluble in the second developer containing the quaternary ammonium hydroxide, and where the method further includes removing the first intermediate structure and an unconverted portion of the second intermediate structure using the quaternary ammonium hydroxide of the second developer to form a mandrel including the converted region of the third material, such that at least part of the mandrel has a critical dimension corresponding to the first depth.

Example 18. The method of one of examples 1 to 17, where the second developer includes any one of or any combination of TetraMethylAmmonium Hydroxide (TMAH), TetraEthylAmmonium Hydroxide (TEAH), TetraPropylAmmonium Hydroxide (TPAH), TetraButylAmmonium Hydroxide (TBAH), and Choline Hydroxide.

Example 19. A method for forming an anti-spacer patterned mask, the method including: providing a first patterned photoresist layer on a substrate, where the first patterned photoresist layer includes a solubility shifting agent therein, and where the first patterned photoresist layer is insoluble in a first developer containing an organic solvent; depositing a first overcoat layer over the first patterned photoresist layer and the substrate, where the first overcoat layer includes a first polymer and a first reactant, where the first overcoat layer is insoluble in the first developer containing the organic solvent; diffusing at least a catalyst portion of the solubility shifting agent from the first patterned photoresist layer into first regions of the first overcoat layer, where the first regions are adjacent the first patterned photoresist layer, and chemically transforming the first regions of the first overcoat layer to anti-spacer regions of a converted material to a first depth into the first overcoat layer using the catalyst portion of the solubility shifting agent as a chemical reaction catalyst, such that the converted material is soluble in the first developer containing the organic solvent; and removing the anti-spacer regions using the organic solvent of the first developer to form an anti-spacer pattern including remaining portions of the first patterned photoresist layer and the first overcoat layer having openings to the substrate corresponding to the anti-spacer regions and where at least part of the openings has a critical dimension corresponding to the first depth.

Example 20. A method for forming an anti-spacer patterned mask, the method including: providing a first patterned photoresist layer on a substrate, where the first patterned photoresist layer includes a first polymer and a first reactant, where the first patterned photoresist layer is insoluble in a first developer containing an organic solvent; depositing a first overcoat layer over the first patterned photoresist layer and the substrate, where the first overcoat layer includes a solubility shifting agent therein, and where the first overcoat layer is insoluble in the first developer containing the organic solvent; diffusing at least a catalyst portion of the solubility shifting agent from the first overcoat layer into outer regions of the first patterned photoresist layer and chemically transforming the outer regions of the first patterned photoresist layer to anti-spacer regions of a converted material to a first depth into the first patterned photoresist layer using the catalyst portion of the solubility shifting agent as a chemical reaction catalyst, such that the converted material is soluble in the first developer containing the organic solvent; and removing the anti-spacer regions using the organic solvent of the first developer to form an anti-spacer pattern including remaining portions of the first overcoat layer and the first patterned photoresist layer having openings to the substrate corresponding to the anti-spacer regions and where at least part of the openings has a critical dimension corresponding to the first depth.

Example 21. A method for forming an anti-spacer patterned mask, the method including: providing a first intermediate structure on a substrate, where the first intermediate structure includes a first material, where the first material includes a solubility shifting agent therein, and where the first material is insoluble in a first developer containing an organic solvent; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is insoluble in the first developer containing the organic solvent; diffusing at least a catalyst portion of the solubility shifting agent from the first material into the first region of the second intermediate structure and chemically transforming the first region of the second intermediate structure to an anti-spacer region of a third material to a first depth into the second intermediate structure using the catalyst portion of the solubility shifting agent as a chemical reaction catalyst, such that the third material is soluble in the first developer containing the organic solvent; and removing the anti-spacer region using the organic solvent of the first developer to form an anti-spacer pattern including remaining portions of the first intermediate structure and the second intermediate structure having an opening to the substrate corresponding to the anti-spacer region and where at least part of the opening has a critical dimension corresponding to the first depth.

Example 22. A method for forming a patterned mask, the method including: providing a first intermediate structure on a substrate, where the first intermediate structure includes a first material, where the first material includes a solubility shifting agent therein, and where the first material is soluble in a first developer containing a quaternary ammonium hydroxide in an aqueous solution; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is soluble in the first developer containing the quaternary ammonium hydroxide; diffusing at least a catalyst portion of the solubility shifting agent from the first material into the first region of the second intermediate structure and chemically transforming the first region of the second intermediate structure to a mandrel region of a third material to a first depth into the second intermediate structure using the catalyst portion of the solubility shifting agent as a chemical reaction catalyst, such that the third material is insoluble in the first developer containing the quaternary ammonium hydroxide; and removing the first intermediate structure and unconverted portions of the second intermediate structure using the quaternary ammonium hydroxide of the first developer to form a mandrel including the mandrel region of the third material, such that at least part of the mandrel has a critical dimension corresponding to the first depth.

Example 23. A method for forming a patterned mask, the method including: providing a first intermediate structure on a substrate, where the first intermediate structure includes a first material, where the first material includes a solubility shifting agent therein, and where the first material is soluble in a first developer containing a quaternary ammonium hydroxide in an aqueous solution, and insoluble in a second developer containing an organic solvent; providing a second intermediate structure on the substrate, where the second intermediate structure includes a second material, where a first region of the second intermediate structure including the second material is adjacent the first material of the first intermediate structure, where the second material includes a first polymer and a first reactant, and where the second material is soluble in the first developer containing the quaternary ammonium hydroxide and insoluble in the second developer containing the organic solvent; diffusing at least a catalyst portion of the solubility shifting agent from the first material into the first region of the second intermediate structure and chemically transforming the first region of the second intermediate structure to a mandrel region of a third material to a first depth into the second intermediate structure using the catalyst portion of the solubility shifting agent as a chemical reaction catalyst, such that the third material is insoluble in the first developer containing the quaternary ammonium hydroxide and soluble in the second developer containing the organic solvent; and removing the first intermediate structure and unconverted portions of the second intermediate structure using the quaternary ammonium hydroxide of the first developer to form a mandrel including the mandrel region of the third material, such that at least part of the mandrel has a critical dimension corresponding to the first depth.

Example 24. A method for forming a patterned mask, the method including: providing a first patterned photoresist layer on a substrate, where the first patterned photoresist layer includes a first material, where the first material includes a solubility shifting agent therein, and where the first material is soluble in a first developer containing a quaternary ammonium hydroxide in an aqueous solution; depositing a first overcoat layer over the first patterned photoresist layer and the substrate, where the first overcoat layer includes a second material, where the second material includes a first polymer and a first reactant, where the second material is soluble in the first developer containing the quaternary ammonium hydroxide; diffusing at least a catalyst portion of the solubility shifting agent from the first patterned photoresist layer into first regions of the first overcoat layer, where the first regions are adjacent the first patterned photoresist layer, and chemically transforming the first regions of the first overcoat layer to mandrel regions of a third material to a first depth into the first overcoat layer using the catalyst portion of the solubility shifting agent as a chemical reaction catalyst, such that the third material is insoluble in the first developer containing the quaternary ammonium hydroxide; and removing the first patterned photoresist layer of the first material and unconverted portions of the first overcoat layer of the second material using the quaternary ammonium hydroxide of the first developer to form a mandrel pattern of mandrels including the mandrel regions of the third material, such that at least part of the mandrels has a critical dimension corresponding to the first depth.

Example 25. A method for forming a patterned mask, the method including: providing a first patterned photoresist layer on a substrate, where the first patterned photoresist layer includes a first material, where the first material includes a first polymer and a first reactant, and where the first material is soluble in a first developer containing a quaternary ammonium hydroxide in an aqueous solution; depositing a first overcoat layer over the first patterned photoresist layer and the substrate, where the first overcoat layer includes a second material, where the second material includes a solubility shifting agent therein, and where the second material is soluble in the first developer containing the quaternary ammonium hydroxide; diffusing at least a catalyst portion of the solubility shifting agent from the first overcoat layer into outer regions of the first patterned photoresist layer and chemically transforming the outer regions of the first patterned photoresist layer to mandrel regions of a third material to a first depth into the first patterned photoresist layer using the catalyst portion of the solubility shifting agent as a chemical reaction catalyst, such that the third material is insoluble in the first developer containing the quaternary ammonium hydroxide; and removing the first patterned photoresist layer of the first material and unconverted portions of the first overcoat layer of the second material using the quaternary ammonium hydroxide of the first developer to form a mandrel pattern of mandrels including the mandrel regions of the third material, such that at least part of the mandrels has a critical dimension corresponding to the first depth.

Example 26. A chemical composition for a photoresist material configured to be used in semiconductor manufacturing, the chemical composition comprising a chemically amplified photosensitive composition including a first polymer, a first reactant, a photoacid generator, and a solvent, wherein the chemically amplified photosensitive composition is configured such that after deposition and before exposure to radiation, the chemically amplified photosensitive composition is insoluble in a first developer containing an organic solvent and is soluble in a second developer containing a quaternary ammonium hydroxide in an aqueous solution.

Example 27. The chemical composition of example 26, further including an additional optional component, such as a quencher.

Example 28. A chemical composition for an overcoat material configured to be used in semiconductor manufacturing (e.g., anti-spacer process flow), the chemical composition comprising a starting overcoat chemical composition that includes a first polymer, a first reactant, a solvent, and may also contain additional optional components, without a PAG, TAG, or SSA, wherein the starting overcoat chemical composition is configured such that after deposition to form an overcoat layer, the overcoat layer is insoluble in a first developer containing an organic solvent and is soluble in a second developer containing a quaternary ammonium hydroxide in an aqueous solution.

Example 29. The chemical composition of example 28, further including an additional optional component, such as a quencher.

Example 30. A pattern forming method comprising: a) providing a semiconductor substrate; b) forming a photoresist film comprising coating the semiconductor substrate with a chemically amplified photosensitive composition including a first polymer, a first reactant, a photoacid generator, and a solvent, wherein the chemically amplified photosensitive composition is configured such that after deposition and before exposure to radiation, the chemically amplified photosensitive composition is insoluble in a first developer containing an organic solvent and is soluble in a second developer containing a quaternary ammonium hydroxide in an aqueous solution; c) exposing the resist film with actinic rays or electromagnetic radiation; and d) developing the resist film with a developer.

Example 31. The pattern forming method of example 30, wherein the developer comprises an organic solvent.

Example 33. The pattern forming method of example 30, wherein the developer comprises propylene glycol methyl ether acetate, propylene glycol methyl ether, N-butyl acetate, 2-heptanone, methyl isobutyl carbinol, isoamyl alcohol, n-butanol, isoamyl ether, cyclohexanone, ethyl lactate, methyl isobutyl ketone, or methyl 2-hydroxyisobutyrate.

While illustrative and example embodiments have been described with reference to illustrative drawings, this description is not intended to be construed in a necessarily limiting sense. Various modifications and combinations of the illustrative and example embodiments, as well as other embodiments, can be apparent to persons skilled in the pertinent art upon referencing the present disclosure. It is therefore intended that the appended claims encompass any and all of such modifications, equivalents, or embodiments.

What is claimed is:

1. A method for forming a patterned mask, the method comprising:
providing a first intermediate structure on a substrate, wherein the first intermediate structure comprises a first material, wherein the first material comprises a solubility shifting agent therein, and wherein the first material is insoluble in a first developer containing an organic solvent;
providing a second intermediate structure on the substrate, wherein the second intermediate structure comprises a second material, wherein a first region of the second intermediate structure including the second material is adjacent the first material of the first intermediate structure, wherein the second material comprises a first polymer and a first reactant, and wherein the second material is insoluble in the first developer containing the organic solvent; and
diffusing at least a catalyst portion of the solubility shifting agent from the first material into the first region of the second intermediate structure and chemically transforming the first region of the second intermediate structure to a converted region of a third material to a first depth into the second intermediate structure using the catalyst portion of the solubility shifting agent as a chemical reaction catalyst, such that the third material is soluble in the first developer containing the organic solvent.

2. The method of claim 1, further comprising removing the converted region using the organic solvent of the first developer to form an anti-spacer pattern comprising remaining portions of the first intermediate structure and the second intermediate structure having an opening to the substrate corresponding to the converted region and wherein at least part of the opening has a critical dimension corresponding to the first depth.

3. The method of claim 2, further comprising depositing the second intermediate structure over the first intermediate structure, wherein the first intermediate structure comprises a first patterned photoresist layer, wherein the second intermediate structure comprises a first overcoat layer.

4. The method of claim 2, further comprising depositing the first intermediate structure over the second intermediate structure, wherein the second intermediate structure comprises a first patterned photoresist layer, wherein the first intermediate structure comprises a first overcoat layer.

5. The method of claim 1, wherein each of the first material and the second material is soluble in a second developer containing a quaternary ammonium hydroxide in an aqueous solution, and wherein the third material is insoluble in the second developer.

6. The method of claim 1, wherein the first polymer comprises para-hydroxystyrene, acrylic acid, methacrylic acid, 2-hydroxyethyl acrylate, 2-hydroxyethyl methacrylate, an acrylate or methacrylate functionalized with a carbohydrate, or any combination thereof.

7. The method of claim 1, wherein the first polymer comprises p-hydroxystyrene and the first reactant comprises a carboxylic acid.

8. The method of claim 1, wherein the solubility shifting agent comprises a free acid that is free of fluorine.

9. The method of claim 8, wherein the free acid comprises trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, or any combination thereof.

10. The method of claim 1, wherein the solubility shifting agent comprises a thermal acid generator that is free of fluorine.

11. The method of claim 10, wherein the thermal acid generator comprises pyridinium perfluorobutanesulfonate, 3-fluoropyridinium perfluorobutanesulfonate, triethylammonium perfluorobutanesulfonate, 3-fluoropyridinium perfluorobutanesulfonate, pyridinium p-toluenesulfonate, 3-fluoropyridinium p-toluenesulfonate, Triethylammonium p-toluenesulfonate, trioctylammonium p-toluenesulfonate, pyridinium 4-dodecylbenzenesulfonate, 3-fluoropyridinium 4-dodecylbenzenesulfonate, triethylammonium 4-dodecylbenzenesulfonate, trioctylammonium 4-dodecylbenzenesulfonate, or any combination thereof.

12. The method of claim 1, wherein the solubility shifting agent comprises a photoacid generator that is free of fluorine.

13. The method of claim 12, wherein the photoacid generator comprises 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, or any combination thereof.

14. The method of claim 1, wherein the organic solvent comprises propylene glycol methyl ether acetate, propylene glycol methyl ether, N-butyl acetate, 2-heptanone, methyl isobutyl carbinol, isoamyl alcohol, n-butanol, isoamyl ether, cyclohexanone, ethyl lactate, methyl isobutyl ketone, methyl 2-hydroxyisobutyrate, or any combination thereof.

15. The method of claim 1, wherein the second material of the second intermediate structure further includes a quencher.

16. The method of claim 1, wherein the first region of the second intermediate structure including the second material is adjacent and in direct physical contact with the first material of the first intermediate structure.

17. The method of claim 1, wherein the first material and the second material are soluble in a second developer containing a quaternary ammonium hydroxide in an aqueous solution, and wherein the third material is insoluble in the second developer containing the quaternary ammonium hydroxide, and wherein the method further comprises removing the first intermediate structure and an unconverted portion of the second intermediate structure using the quaternary ammonium hydroxide of the second developer to form a mandrel comprising the converted region of the third material, such that at least part of the mandrel has a critical dimension corresponding to the first depth.

18. The method of claim 17, wherein the second developer comprises any one of or any combination of TetraMethylAmmonium Hydroxide (TMAH), TetraEthylAmmonium Hydroxide (TEAH), TetraPropylAmmonium Hydroxide (TPAH), TetraButylAmmonium Hydroxide (TBAH), and Choline Hydroxide.

19. A method for forming an anti-spacer patterned mask, the method comprising:
providing a first patterned photoresist layer on a substrate, wherein the first patterned photoresist layer comprises a solubility shifting agent therein, and wherein the first patterned photoresist layer is insoluble in a first developer containing an organic solvent;
depositing a first overcoat layer over the first patterned photoresist layer and the substrate, wherein the first overcoat layer comprises a first polymer and a first reactant, wherein the first overcoat layer is insoluble in the first developer containing the organic solvent;
diffusing at least a catalyst portion of the solubility shifting agent from the first patterned photoresist layer into first regions of the first overcoat layer, wherein the first regions are adjacent the first patterned photoresist layer, and chemically transforming the first regions of the first overcoat layer to anti-spacer regions of a converted material to a first depth into the first overcoat layer using the catalyst portion of the solubility shifting agent as a chemical reaction catalyst, such that the converted material is soluble in the first developer containing the organic solvent; and
removing the anti-spacer regions using the organic solvent of the first developer to form an anti-spacer pattern comprising remaining portions of the first patterned photoresist layer and the first overcoat layer having openings to the substrate corresponding to the anti-spacer regions and wherein at least part of the openings has a critical dimension corresponding to the first depth.

20. A chemical composition for a photoresist material configured to be used in semiconductor manufacturing, the chemical composition comprising a chemically amplified photosensitive composition including a first polymer, a first reactant, a photoacid generator, and a solvent, wherein the chemically amplified photosensitive composition is configured such that after deposition and before exposure to radiation, the chemically amplified photosensitive composition is insoluble in a first developer containing an organic solvent and is soluble in a second developer containing a quaternary ammonium hydroxide in an aqueous solution.
